(19) United States
(12) Patent Application Publication
(10) Pub. No.: US 2024/0297202 A1
(43) Pub. Date: Sep. 5, 2024

(54) IMAGING ELEMENT, IMAGING DEVICE, AND METHOD OF MANUFACTURING IMAGING ELEMENT

(71) Applicant: SONY SEMICONDUCTOR SOLUTIONS CORPORATION, KANAGAWA (JP)

(72) Inventors: YILUN HE, KANAGAWA (JP); TAKASHI MACHIDA, KANAGAWA (JP)

(21) Appl. No.: 18/251,630

(22) PCT Filed: Nov. 4, 2021
(86) PCT No.: PCT/JP2021/040587

§ 371 Date: May 3, 2023

(30) Foreign Application Priority Data
Nov. 11, 2020 (JP) 2020-188206

(51) Int. Cl. H01L 27/148; H01L 27/146; H04N 25/62

(52) U.S. Cl. CPC H01L 27/14818; H01L 27/14689; H04N 25/62

(57) ABSTRACT

To prevent leakage of incident light to a charge holding unit of an imaging element. The pixel includes a photoelectric conversion unit disposed on a side of the light receiving face of the semiconductor substrate, a charge holding unit disposed on a side different from the light receiving face of the semiconductor substrate, and a charge transfer unit that transfers a charge to the charge holding unit, and is configured to have a rectangular shape in a light receiving face view. The charge holding unit light shielding film is configured to have a band shape adjacent to three sides including a first side that is one of the sides of the rectangle and parallel to the first side in a light receiving face view, is adjacent to a semiconductor region including the charge transfer unit in a light receiving face view, and is disposed in the pixel between the photoelectric conversion unit and the charge holding unit to shield incident light. The charge transfer unit light shielding film is configured to have a band shape adjacent to three sides including a second side that is a side facing the first side in a light receiving face view and parallel to the second side, and is configured to be disposed in the pixel between the photoelectric conversion unit and the charge transfer unit to shield incident light and have a shape which has an end portion overlapping an end portion of the charge holding unit light shielding film in a light receiving face view.

### FIELD

The present disclosure relates to an imaging element, an imaging device, and a method of manufacturing an imaging element.

### BACKGROUND

A global shutter type imaging element that simultaneously exposes all pixels is used as an imaging element in which a plurality of pixels is disposed. In this global shutter system, after all pixels are exposed simultaneously, image signals generated by the pixels are sequentially read for each row. Since a difference in time occurs between exposure and reading of image signals, a charge holding unit that holds a charge generated by photoelectric conversion of incident light in an exposure period is disposed for each pixel. Since charges are held in the charge holding unit for a relatively long period, it is necessary to prevent entry of incident light. This is because a charge is generated by photoelectric conversion of incident light in the charge holding unit, and noise is mixed in the image signal. By disposing a light shielding unit between the photoelectric conversion unit irradiated with the incident light and the charge holding unit to separate them, entry of the incident light into the charge holding unit can be prevented.

On the other hand, in order to cope with downsizing of a pixel size accompanying high resolution of an imaging element, an imaging element including a pixel in which a photoelectric conversion unit and a charge holding unit are disposed at positions overlapping in a thickness direction of a semiconductor substrate has been proposed. In this imaging element, a charge transfer unit that transfers a charge in a thickness direction of a semiconductor substrate is disposed, and a charge generated by the photoelectric conversion unit is held in a charge holding unit disposed inside the semiconductor substrate. In such an imaging element, an imaging element having two band-shaped light shielding portions disposed inside a semiconductor substrate has been proposed (see, for example, Patent Literature 1).

In the above-described conventional technique, a band-shaped light shielding portion that shields the charge holding unit and a band-shaped light shielding portion that shields the charge transfer unit are disposed at different depths of the semiconductor substrate and are alternately disposed in a light receiving face view to shield incident light.

### CITATION LIST

### Patent Literature

Patent Literature 1: WO 2019/240207 A

### SUMMARY

### Technical Problem

In the above-described conventional technique, the end portions of the band-shaped light shielding portion that shields the charge holding units disposed alternately and the band-shaped light shielding portion that shields the charge transfer unit are configured to contact each other in a light receiving face view. For this reason, incident light bypassing the end portions of the two band-shaped light shielding portions reaches the charge holding unit, and there is a problem that noise is mixed in the image signal.

Therefore, the present disclosure proposes an imaging element, an imaging device, and a method of manufacturing the imaging element that prevent leakage of incident light to a charge holding unit of an imaging element disposed at a position where the photoelectric conversion unit and the charge holding unit overlap in a thickness direction of a semiconductor substrate and reduce noise of an image signal.

### Solution to Problem

An imaging element according to the present disclosure includes: a pixel that includes a photoelectric conversion unit that is disposed on a light receiving face of a semiconductor substrate and performs photoelectric conversion on incident light, a charge holding unit that is disposed on a side different from a side of the light receiving face of the semiconductor substrate and holds a charge generated by the photoelectric conversion, and a charge transfer unit that transfers the generated charge to the charge holding unit, the pixel being configured to have a rectangular shape in a light receiving face view; a charge holding unit light shielding film configured to have a band shape adjacent to three sides including a first side that is one of sides of the rectangle and parallel to the first side in a light receiving face view, being adjacent to a semiconductor region including the charge transfer unit in a light receiving face view, and being disposed in the pixel between the photoelectric conversion unit and the charge holding unit to shield incident light; and a charge transfer unit light shielding film configured to have a band shape adjacent to three sides including a second side that is a side opposite to the first side and parallel to the second side in a light receiving face view, and configured to have a shape disposed in the pixel between the photoelectric conversion unit and the charge transfer unit to shield incident light and have an end portion overlapping an end portion of the charge holding unit light shielding film in a light receiving face view.

### BRIEF DESCRIPTION OF DRAWINGS

FIG. 1 is a diagram illustrating a configuration example of an imaging element according to an embodiment of the present disclosure.

FIG. 2 is a diagram illustrating a configuration example of a pixel according to the first embodiment of the present disclosure.

FIG. 3 is a cross-sectional view illustrating a configuration example of a pixel according to the first embodiment of the present disclosure.

FIG. 4 is a diagram illustrating configuration examples of a charge holding unit light shielding film and a charge transfer unit light shielding film according to the first embodiment of the present disclosure.

FIG. 5A is a plan view illustrating a configuration example of a groove portion according to the first embodiment of the present disclosure.

FIG. 5B is a cross-sectional view illustrating a configuration example of a groove portion according to the first embodiment of the present disclosure.

FIG. 6A is a diagram illustrating an example of a method of manufacturing a charge holding unit adjacent gap according to the first embodiment of the present disclosure.

FIG. 6B is a diagram illustrating an example of a method of manufacturing the charge holding unit adjacent gap according to the first embodiment of the present disclosure.

FIG. 6C is a diagram illustrating an example of a method of manufacturing the charge holding unit adjacent gap according to the first embodiment of the present disclosure.

FIG. 6D is a diagram illustrating an example of a method of manufacturing the charge holding unit adjacent gap according to the first embodiment of the present disclosure.

FIG. 7A is a diagram illustrating an example of a method of etching the charge holding unit adjacent gap according to the first embodiment of the present disclosure.

FIG. 7B is a diagram illustrating an example of a method of etching the charge holding unit adjacent gap according to the first embodiment of the present disclosure.

FIG. 7C is a diagram illustrating an example of a method of etching the charge holding unit adjacent gap according to the first embodiment of the present disclosure.

FIG. 8A is a diagram illustrating another example of a method of etching the charge holding unit adjacent gap according to the first embodiment of the present disclosure.

FIG. 8B is a diagram illustrating another example of a method of etching the charge holding unit adjacent gap according to the first embodiment of the present disclosure.

FIG. 9A is a diagram illustrating an example of a method of forming a charge holding unit adjacent gap and a charge transfer unit adjacent gap according to the first embodiment of the present disclosure.

FIG. 9B is a diagram illustrating an example of a method of forming the charge holding unit adjacent gap and the charge transfer unit adjacent gap according to the first embodiment of the present disclosure.

FIG. 9C is a diagram illustrating an example of a method of forming the charge holding unit adjacent gap and the charge transfer unit adjacent gap according to the first embodiment of the present disclosure.

FIG. 9D is a diagram illustrating an example of a method of forming the charge holding unit adjacent gap and the charge transfer unit adjacent gap according to the first embodiment of the present disclosure.

FIG. 9E is a diagram illustrating an example of a method of forming the charge holding unit adjacent gap and the charge transfer unit adjacent gap according to the first embodiment of the present disclosure.

FIG. 10A is a diagram illustrating an example of a method of manufacturing an imaging element according to the first embodiment of the present disclosure.

FIG. 10B is a diagram illustrating an example of the method of manufacturing the imaging element according to the first embodiment of the present disclosure.

FIG. 10C is a diagram illustrating an example of a method of manufacturing the imaging element according to the first embodiment of the present disclosure.

FIG. 10D is a diagram illustrating an example of a method of manufacturing the imaging element according to the first embodiment of the present disclosure.

FIG. 10E is a diagram illustrating an example of a method of manufacturing the imaging element according to the first embodiment of the present disclosure.

FIG. 10F is a diagram illustrating an example of a method of manufacturing the imaging element according to the first embodiment of the present disclosure.

FIG. 10G is a diagram illustrating an example of a method of manufacturing the imaging element according to the first embodiment of the present disclosure.

FIG. 10H is a diagram illustrating an example of a method of manufacturing the imaging element according to the first embodiment of the present disclosure.

FIG. 10I is a diagram illustrating an example of a method of manufacturing the imaging element according to the first embodiment of the present disclosure.

FIG. 10J is a diagram illustrating an example of a method of manufacturing the imaging element according to the first embodiment of the present disclosure.

FIG. 11 is a plan view illustrating a configuration example of a groove portion according to the second embodiment of the present disclosure.

FIG. 12 is a plan view illustrating a configuration example of a groove portion according to the third embodiment of the present disclosure.

FIG. 13 is a plan view illustrating a configuration example of the groove portion according to a modification of the third embodiment of the present disclosure.

FIG. 14 is a cross-sectional view illustrating a configuration example of a pixel according to the fourth embodiment of the present disclosure.

FIG. 15 is a cross-sectional view illustrating a configuration example of a pixel according to the fifth embodiment of the present disclosure.

FIG. 16 is a plan view illustrating a configuration example of a groove portion according to a modification of the embodiment of the present disclosure.

FIG. 17 is a plan view illustrating a configuration example of a first charge holding unit according to a modification of an embodiment of the present disclosure.

FIG. 18 is a diagram illustrating a configuration example of an imaging device to which the technology according to the present disclosure can be applied.

### DESCRIPTION OF EMBODIMENTS

Hereinafter, the embodiments of the present disclosure will be described in detail with reference to the drawings. The description will be given in the following order. In the following embodiments, the same parts are denoted by the same reference signs, and a duplicate description will be omitted.
1. First embodiment
2. Second embodiment
3. Third embodiment
4. Fourth embodiment
5. Fifth embodiment
6. Modifications
7. Configuration example of imaging device

### 1. First Embodiment

### [Configuration of Imaging Element]

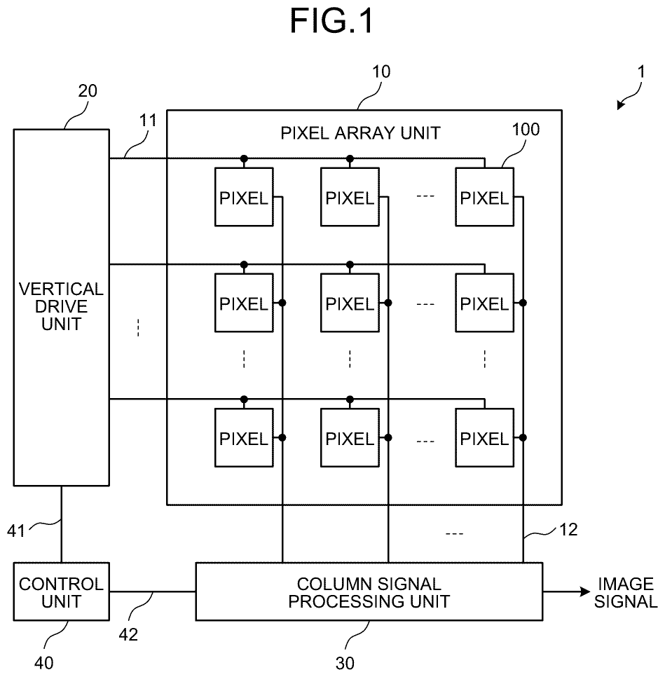

FIG. 1 is a diagram illustrating a configuration example of an imaging element according to an embodiment of the present disclosure. FIG. 1 is a block diagram illustrating a configuration example of an imaging element 1. The imaging element 1 is a semiconductor element that generates image data of a subject. The imaging element 1 includes a pixel array unit 10, a vertical drive unit 20, a column signal processing unit 30, and a control unit 40.

The pixel array unit 10 is configured by disposing a plurality of pixels 100. The pixel array unit 10 in FIG. 1 illustrates an example in which a plurality of pixels 100 is disposed in a shape of a two-dimensional matrix. Here, the pixel 100 includes a photoelectric conversion unit that performs photoelectric conversion on incident light, and generates an image signal of a subject based on the emitted incident light. For example, a photodiode can be included in the photoelectric conversion unit. Signal lines 11 and 12 are wired to each pixel 100. The pixel 100 is controlled by a control signal transmitted by the signal line 11 to generate an image signal to output the generated image signal via the signal line 12. Note that the signal line 11 is disposed for each row of the shape of the two-dimensional matrix, and is commonly wired to the plurality of pixels 100 disposed in one row. The signal line 12 is disposed for each column of the shape of the two-dimensional matrix, and is commonly wired to the plurality of pixels 100 disposed in one column.

The vertical drive unit 20 generates a control signal of the pixel 100 described above. The vertical drive unit 20 in FIG. 1 generates a control signal for each row of the two-dimensional matrix of the pixel array unit 10 and sequentially outputs the control signal via the signal line 11.

The column signal processing unit 30 processes the image signal generated by the pixel 100. The column signal processing unit 30 FIG. 1 simultaneously processes the image signals, transmitted via the signal line 12, from the plurality of pixels 100 disposed in one row of the pixel array unit 10. As this processing, for example, analog-digital conversion for converting an analog image signal generated by the pixel 100 into a digital image signal and correlated double sampling (CDS) for removing an offset error of the image signal can be performed. The processed image signal is output to a circuit or the like outside the imaging element 1.

The control unit 40 controls the vertical drive unit 20 and the column signal processing unit 30. The control unit 40 in FIG. 1 outputs control signals via signal lines 41 and 42 to control the vertical drive unit 20 and the column signal processing unit 30, respectively. Note that the imaging element 1 in FIG. 1 is an example of an imaging element described in the claims. Furthermore, the pixel array unit 10 in FIG. 1 can be assumed as an example of an imaging element described in the claims. In this case, the column signal processing unit 30 in FIG. 1 corresponds to an example of a processing circuit described in the claims, and the imaging element 1 in FIG. 1 corresponds to an example of an imaging device described in the claims.

### [Configuration of Pixel]

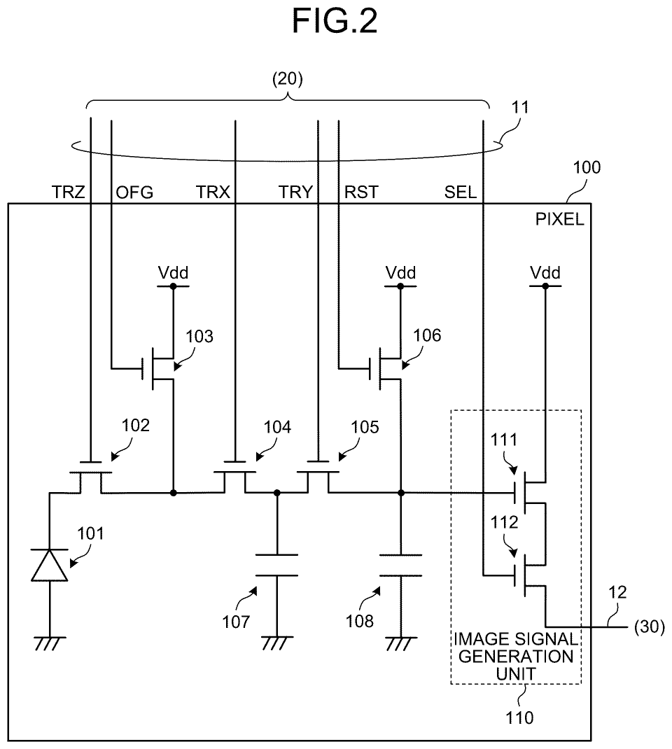

FIG. 2 is a diagram illustrating a configuration example of a pixel according to the first embodiment of the present disclosure. FIG. 2 is a circuit diagram illustrating a configuration example of the pixel 100. The pixel 100 in FIG. 2 includes a photoelectric conversion unit 101, a first charge transfer unit 102, an overflow gate 103, a second charge transfer unit 104, a third charge transfer unit 105, a first charge holding unit 107, and a second charge holding unit 108. Furthermore, the imaging element 1 further includes a reset unit 106 and MOS transistors 111 and 112. Note that the MOS transistors 111 and 112 constitute an image signal generation unit 110.

An n-channel MOS transistor can be used for each of the first charge transfer unit 102, the overflow gate 103, the second charge transfer unit 104, the third charge transfer unit 105, the reset unit 106, and the MOS transistors 111 and 112. Furthermore, the signal line 11 connected to the pixel 100 includes a signal line TRZ, a signal line OFG, a signal line TRX, a signal line TRY, a signal line RST, and a signal line SEL. Furthermore, a power supply line Vdd for supplying power is wired to the pixel 100.

The anode of the photoelectric conversion unit 101 is grounded, and the cathode is connected to the source of the first charge transfer unit 102. The drain of the first charge transfer unit 102 is connected to the source of the second charge transfer unit 104 and the source of the overflow gate 103. The drain of the second charge transfer unit 104 is connected to one end of the first charge holding unit 107 and the source of the third charge transfer unit 105. The other end of the first charge holding unit 107 is grounded. The drain of the third charge transfer unit 105 is connected to the source of the reset unit 106, the gate of the MOS transistor 111, and one end of the second charge holding unit 108. The other end of the second charge holding unit 108 is grounded. The source of the MOS transistor 111 is connected to the drain of the MOS transistor 112, and the source of the MOS transistor 112 is connected to the signal line 12.

Gates of the first charge transfer unit 102, the overflow gate 103, the second charge transfer unit 104, and the third charge transfer unit 105 are wired to the signal line TRZ, the signal line OFG, the signal line TRX, and the signal line TRY, respectively. Gates of the reset unit 106 and the MOS transistor 112 are connected to a signal line RST and a signal line SEL, respectively. The drain of the overflow gate 103, the drain of the reset unit 106, and the drain of the MOS transistor 111 are connected to the power supply line Vdd.

The photoelectric conversion unit 101 is an element that performs photoelectric conversion on incident light. The photoelectric conversion unit 101 generates and holds a charge by photoelectric conversion.

The first charge transfer unit 102 is an element that transfers the charge held in the photoelectric conversion unit 101 to the second charge transfer unit 104. The first charge transfer unit 102 is controlled by a control signal transmitted by the signal line TRZ. Note that, in the first charge transfer unit 102, an overflow path through which the charge overflowing from the photoelectric conversion unit 101 passes is formed immediately below the gate. As will be described later, the first charge transfer unit 102 includes a vertical transistor that transfers a charge in the thickness direction of the semiconductor substrate.

The overflow gate 103 is an element that discharges the charge overflowing from the photoelectric conversion unit 101. In the overflow gate 103, an overflow path through which the charge having overflowed from the photoelectric conversion unit 101 passes is formed immediately below the gate, and the charge having overflowed from the photoelectric conversion unit 101 together with the overflow path of the first charge transfer unit 102 is discharged to the power supply line Vdd. The overflow gate 103 further resets the photoelectric conversion unit 101. The overflow gate 103 is controlled by a control signal transmitted by the signal line OFG.

The second charge transfer unit 104 is an element that transfers a charge. The second charge transfer unit 104 transfers the charge transferred by the first charge transfer unit 102 to the first charge holding unit 107. The second charge transfer unit 104 is controlled by a control signal transmitted by the signal line TRX.

The first charge holding unit 107 is an element that holds a charge. The first charge holding unit 107 includes a semiconductor region formed in a semiconductor substrate, and holds the charge transferred by the second charge transfer unit 104. Note that the potential of the first charge holding unit 107 is controlled by the gate of the second charge transfer unit 104 and the gate of the third charge transfer unit 105.

The third charge transfer unit 105 is an element that transfers the charge held in the first charge holding unit 107 to the second charge holding unit 108. The third charge transfer unit 105 is controlled by a control signal transmitted by the signal line TRY.

The second charge holding unit 108 is an element that holds a charge. The second charge holding unit 108 can be configured by a semiconductor region formed in a semiconductor substrate.

The reset unit 106 resets the second charge holding unit 108. The reset unit 106 is controlled by a control signal transmitted by the signal line RST.

The MOS transistor 111 is an element that generates an image signal according to the charge held in the second charge holding unit 108. The generated image signal is output to the source terminal.

The MOS transistor 112 is an element that outputs an image signal generated by the MOS transistor 111 to the signal line 12. The MOS transistor 112 is controlled by a control signal transmitted by the signal line SEL.

A generation procedure of the image signal in the pixel 100 in FIG. 2 will be described. First, the overflow gate 103 and the first charge transfer unit 102 are made conductive to discharge the charge held in the photoelectric conversion unit 101 to the power supply line Vdd, and the photoelectric conversion unit 101 is reset. By resetting the photoelectric conversion unit 101, the exposure period is started.

After a lapse of a predetermined exposure period, the reset unit 106 and the third charge transfer unit 105 are made conductive to discharge the charges of the first charge holding unit 107 and the second charge holding unit 108 to the power supply line Vdd, and the first charge holding unit 107 and the second charge holding unit 108 are reset. After this reset, the first charge transfer unit 102 and the second charge transfer unit 104 are made conductive, and the charge held in the photoelectric conversion unit 101 during the exposure period is transferred to the first charge holding unit 107.

Next, the third charge transfer unit 105 is made conductive, and the charge held in the first charge holding unit 107 is transferred to and held in the second charge holding unit 108. As a result, the MOS transistor 111 generates an image signal corresponding to the charge held in the second charge holding unit 108. By conducting the MOS transistor 112, an image signal is output to the signal line 12. The image signal can be generated by the above procedure.

Among the above-described procedures, a procedure from resetting of the photoelectric conversion unit 101 to transfer of the charge held in the photoelectric conversion unit 101 to the first charge holding unit 107 is simultaneously performed in the pixel 100 disposed in the pixel array unit 10. The subsequent procedure up to the output of the image signal is sequentially performed for each row of the pixels 100 disposed in the pixel array unit 10. As a result, a global shutter can be realized. As described above, the first charge holding unit 107 holds the charge generated by the photoelectric conversion during the exposure period in the period from the end of the exposure period to the generation of the image signal.

### [Configuration of Pixel]

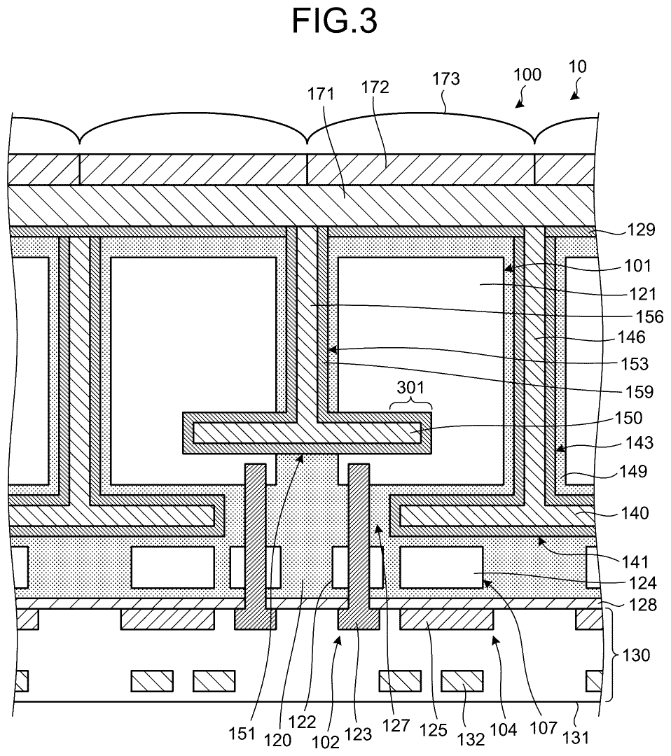

FIG. 3 is a cross-sectional view illustrating a configuration example of a pixel according to the first embodiment of the present disclosure. FIG. 3 is a cross-sectional view illustrating a configuration example of the pixel 100 disposed in the pixel array unit 10. The pixel 100 in FIG. 3 includes a semiconductor substrate 120, a wiring region 130, a charge holding unit light shielding film 140, a charge transfer unit light shielding film 150, a planarizing film 171, a color filter 172, and an on-chip lens 173.

The semiconductor substrate 120 is a semiconductor substrate on which a diffusion region of the element of the pixel 100 is formed. The semiconductor substrate 120 can be made of, for example, silicon (Si). The diffusion region of the element of the pixel 100 is formed in a well region formed in the semiconductor substrate 120. For convenience, the semiconductor substrate 120 in FIG. 3 is assumed to have a p-type well region. By disposing an n-type or p-type semiconductor region in the p-type well region, a diffusion region of the element can be formed. A white rectangle of the semiconductor substrate 120 in FIG. 3 represents a semiconductor region. In FIG. 3, the photoelectric conversion unit 101, the first charge transfer unit 102, the second charge transfer unit 104, and the first charge holding unit 107 are illustrated. Further, an insulating film 128 is disposed on the front face of the semiconductor substrate 120. On the other hand, an insulating film 129 is disposed on the back face of the semiconductor substrate 120. Note that the semiconductor substrate 120 includes a face of a plane direction (111) orthogonal to the thickness direction. For example, the front surface of the semiconductor substrate 120 corresponds to the face of the plane direction (111).

The photoelectric conversion unit 101 includes an n-type semiconductor region 121. Specifically, a photodiode constituted by a pn junction at an interface between the n-type semiconductor region 121 and a surrounding p-type well region corresponds to the photoelectric conversion unit 101. Among the charges generated by the photoelectric conversion of the photoelectric conversion unit 101, electrons are held in the n-type semiconductor region 121. As illustrated in FIG. 3, the photoelectric conversion unit 101 is disposed near the back surface of the semiconductor substrate 120.

The first charge transfer unit 102 is a MOS transistor including the n-type semiconductor region 121, an n-type semiconductor region 122, and a gate electrode 123. The gate electrode 123 includes an electrode portion disposed on the front surface of the semiconductor substrate 120 and a columnar portion disposed under the electrode. The n-type semiconductor region 121 and the n-type semiconductor region 122 correspond to a source region and a drain region, respectively. The charge in the semiconductor region 121 of the photoelectric conversion unit 101 disposed toward the back face of the semiconductor substrate 120 can be transferred to the semiconductor region 122 toward the front face of the semiconductor substrate 120 by the gate electrode 123 having the columnar portion. Specifically, by applying a positive gate voltage to the gate electrode 123, a channel is formed in the semiconductor substrate 120 adjacent to the gate electrode 123, and charges move along the channel. In this manner, the first charge transfer unit 102 constitutes a vertical transistor. The insulating film 128 between the gate electrode 123 and the semiconductor substrate 120 corresponds to a gate insulating film. Although not illustrated for convenience, a gate insulating film is also disposed around the columnar portion of the gate electrode 123.

The second charge transfer unit 104 includes the n-type semiconductor region 122, an n-type semiconductor region 124, and a gate electrode 125. By applying a positive gate voltage to the gate electrode 125, a channel is formed between the n-type semiconductor region 122 and the n-type semiconductor region 124, and charges are transferred. The insulating film 128 between the gate electrode 125 and the semiconductor substrate 120 corresponds to a gate insulating film.

The first charge holding unit 107 includes the n-type semiconductor region 124. The n-type semiconductor region 124 is a semiconductor region also serving as a drain region of the second charge transfer unit 104 described above. The gate electrode 125 is formed in a shape that covers the front face of the n-type semiconductor region 124. When a positive gate voltage is applied to the gate electrode 125, the potential of the n-type semiconductor region 124 constituting the first charge holding unit 107 can be deepened. As a result, all the charges held in the n-type semiconductor region 121 of the photoelectric conversion unit 101 can be transferred to the first charge holding unit 107.

The wiring region 130 is a region in which wiring for transmitting a signal or the like to the element of the pixel 100 is disposed. The wiring region 130 is disposed on the front face of the semiconductor substrate 120. The wiring region 130 includes wiring 132 and an insulating layer 131. The wiring 132 transmits a signal or the like to the element. The wiring 132 can be made of metal such as copper (Cu), for example. The insulating layer 131 insulates the wiring 132. The insulating layer 131 can be made of, for example, an insulator such as silicon oxide (SiO₂).

The planarizing film 171 is a film that planarizes the back face of the semiconductor substrate 120. The planarizing film 171 can be made of, for example, SiO₂.

The color filter 172 is an optical filter that emits incident light having a predetermined wavelength among the incident light. As the color filter 172, respective color filters 172 that transmits red light, green light, and blue light can be used.

The on-chip lens 173 is a lens that condenses incident light. The on-chip lens 173 condenses incident light on the photoelectric conversion unit 101.

As described above, in the pixel 100, the photoelectric conversion unit 101 is irradiated with incident light from the back face of the semiconductor substrate 120 to generate an image signal. Such an imaging element is referred to as a back-irradiation imaging element. Note that the back face of the semiconductor substrate 120 corresponds to a light receiving face that receives incident light. As described later, the pixel 100 is formed in a rectangular shape in a light receiving face view.

The charge holding unit light shielding film 140 is disposed between the photoelectric conversion unit 101 and the first charge holding unit 107 to shield incident light. The charge holding unit light shielding film 140 shields light that passes through the photoelectric conversion unit 101 and enters the first charge holding unit 107. The charge holding unit light shielding film 140 is formed in a band shape covering the first charge holding unit 107 in a light receiving face view. The direction of the band is a direction perpendicular to the paper face in FIG. 3. By disposing the band-shaped charge holding unit light shielding film 140, the band-shaped regions 127 of the semiconductor substrate 120 are formed adjacent to each other in the light receiving face view. The first charge transfer unit 102 is disposed in this region 127.

Furthermore, the charge holding unit light shielding film 140 can be formed by disposing a light shielding member in a charge holding unit adjacent gap 141 that is a band-shaped gap formed in the semiconductor substrate 120. A member that reflects incident light, for example, aluminum (Al) can be used for the light shielding member. Furthermore, a member that absorbs incident light, for example, tungsten (W) can also be used for the light shielding member. As illustrated in FIG. 3, the charge holding unit light shielding film 140 can be disposed in the charge holding unit adjacent gap 141 formed across the two adjacent pixels 100.

The charge transfer unit light shielding film 150 is disposed between the photoelectric conversion unit 101 and the first charge transfer unit 102 to shield incident light. The charge transfer unit light shielding film 150 shields light incident on the first charge holding unit 107 via the above-described region 127. The charge transfer unit light shielding film 150 is formed in a band shape covering the region 127 in a light receiving face view. The direction of this band is the same as the direction of the charge holding unit light shielding film 140. Furthermore, the charge transfer unit light shielding film 150 is configured to have a shape in which an end portion overlaps the charge holding unit light shielding film 140. In FIG. 3, this overlapping portion is described as an overlapping portion 301.

Furthermore, the charge transfer unit light shielding film 150 can be formed by disposing a light shielding member in a charge transfer unit adjacent gap 151 that is a band-shaped gap formed in the semiconductor substrate 120. A light shielding member similar to the charge holding unit light shielding film 140 can be used for the light shielding member. Furthermore, as in the charge holding unit adjacent gap 141, the charge transfer unit light shielding film 150 can be disposed in the charge transfer unit adjacent gap 151 formed across the two adjacent pixels 100.

Note that the charge holding unit light shielding film 140 and the charge transfer unit light shielding film 150 can be made of a member that reflects incident light. In this case, since the incident light is reflected toward the photoelectric conversion unit 101 by the charge holding unit light shielding film 140 and the charge transfer unit light shielding film 150, the sensitivity of the pixel 100 can be improved. Furthermore, the charge holding unit light shielding film 140 and the charge transfer unit light shielding film 150 can also be made of a member that absorbs incident light. In this case, since the incident light transmitted through the photoelectric conversion unit 101 is absorbed by the charge holding unit light shielding film 140 and the charge transfer unit light shielding film 150, the light incident on the first charge holding unit 107 can be reduced. Noise of the image signal can be reduced. Furthermore, a member that absorbs incident light may be used for the charge holding unit light shielding film 140, and a member that reflects incident light may be used for the charge transfer unit light shielding film 150. In this case, the incident light can be reflected by the charge transfer unit light shielding film 150 disposed close to the light receiving face, and the incident light can be absorbed by the charge holding unit light shielding film 140 disposed in the vicinity of the first charge holding unit 107. The sensitivity of the pixel 100 can be improved, and noise of an image signal can be reduced.

A light shielding wall that shields incident light can be disposed on the semiconductor substrate 120 at the boundary of the pixels 100. A light shielding walls 146 and 156 are illustrated in FIG. 3. The light shielding wall 146 is a light shielding wall configured to have a depth in contact with the charge holding unit light shielding film 140. The light shielding wall 146 is disposed in a groove portion 143 formed at a boundary between the pixels 100. The groove portion 143 is a groove having a depth reaching the charge holding unit adjacent gap 141 from the back face of the semiconductor substrate 120. The light shielding wall 146 can be formed by disposing the light shielding member in the groove portion 143.

The light shielding wall 156 is a light shielding wall configured to have a depth in contact with the charge transfer unit light shielding film 150. The light shielding wall 146 is disposed in a groove portion 153 formed at a boundary between the pixels 100. The groove portion 153 is a groove having a depth reaching the charge transfer unit adjacent gap 151 from the back face of the semiconductor substrate 120. The light shielding wall 156 can be formed by disposing the light shielding member in the groove portion 153.

As will be described later, in the semiconductor substrate 120 at the boundary of the pixel 100, light shielding walls 145 to 147 having a depth in contact with the charge holding unit light shielding film 140 and light shielding walls 155 to 157 having a depth in contact with the charge transfer unit light shielding film 150 are disposed. The light shielding walls 145 to 147 and the light shielding walls 155 to 157 can shield incident light obliquely incident from the adjacent pixels 100. Furthermore, the first charge holding unit 107 can be shielded from light by the charge holding unit light shielding film 140 and the charge transfer unit light shielding film 150 having shapes that are disposed at different depths and overlap with each other in a light receiving face view.

### [Configuration of Charge Holding Unit Light Shielding Film and Charge Transfer Unit Light Shielding Film]

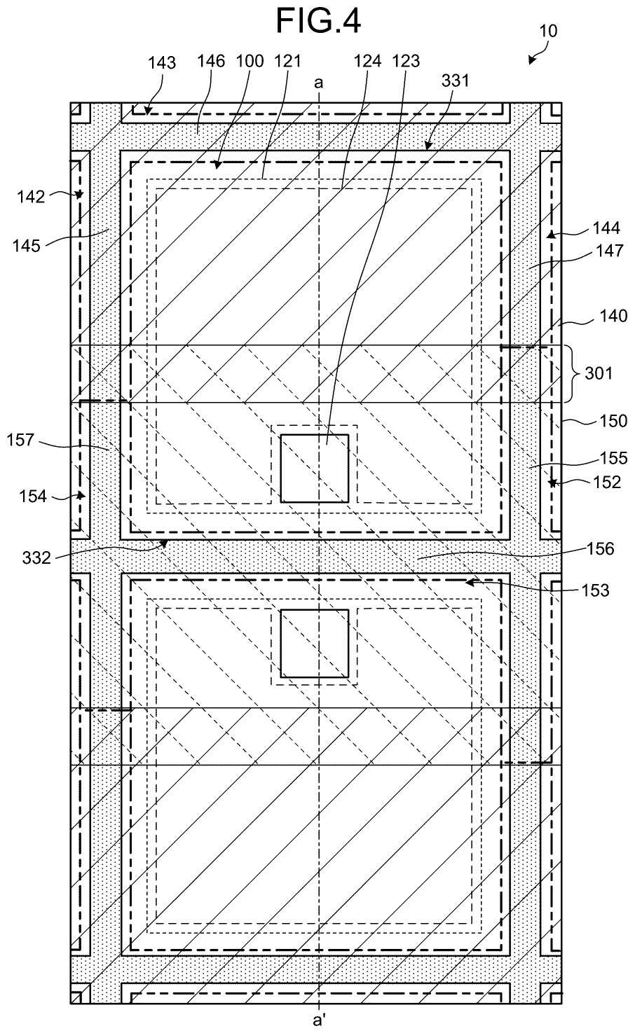

FIG. 4 is a diagram illustrating a configuration example of the charge holding unit light shielding film and the charge transfer unit light shielding film according to the first embodiment of the present disclosure. FIG. 4 is a plan view of the pixel 100 when viewed from the back face of the semiconductor substrate 120. In FIG. 4, an outer solid rectangle represents the pixel 100. An inner solid rectangle represents the gate electrode 123 of the first charge transfer unit 102. A rectangle of a broken line represents the semiconductor region 121. A dotted rectangle represents the semiconductor region 124. A hatched region with a solid line represents the charge holding unit light shielding film 140. A hatched region of a broken line represents the charge transfer unit light shielding film 150. Note that FIG. 3 corresponds to a cross-sectional view taken along line a-a′ in FIG. 4.

Each of the charge holding unit light shielding film 140 and the charge transfer unit light shielding film 150 is configured in a shape adjacent to three sides of the rectangular pixel 100. In FIG. 4, the charge holding unit light shielding film 140 is adjacent to three sides including an upper side of the pixel 100, and the charge transfer unit light shielding film 150 is adjacent to three sides including a lower side of the pixel 100. In a case where the upper side and the lower side are referred to as a first side 331 and a second side 332, respectively, the first side 331 and the second side 332 correspond to sides facing each other in the rectangular pixel 100. The charge holding unit light shielding film 140 is configured to have a band shape in a direction parallel to the first side 331, and the charge transfer unit light shielding film 150 is configured to have a band shape in a direction parallel to the second side 332.

The light shielding walls 145 to 147 and the light shielding walls 155 to 157 are disposed at the boundary of the pixel 100. The light shielding walls 145 to 147 are disposed on the sides of the pixel 100 where the charge holding unit light shielding film 140 is disposed, and are configured to have a depth reaching the charge holding unit light shielding film 140 from the back face of the semiconductor substrate 120. The light shielding wall 146 is disposed on the first side 331 of the boundary of the pixel 100, and the light shielding walls 145 and 147 are disposed on sides adjacent to the first side 331. The light shielding walls 155 to 157 are disposed on the sides of the pixel 100 where the charge transfer unit light shielding film 150 is disposed, and are configured to have a depth reaching the charge transfer unit light shielding film 150 from the back face of the semiconductor substrate 120. The light shielding wall 156 is disposed on the second side 332 of the boundary of the pixel 100, and the light shielding walls 155 and 157 are disposed on sides adjacent to the second side 332. The gate electrode 125 of the first charge transfer unit 102 in FIG. 4 can be disposed close to the second side 332.

The light shielding walls 145 to 147 and the light shielding walls 155 to 157 are disposed in groove portions formed at a boundary of the pixel 100. A two-dot chain line in FIG. 4 represents a groove portion. The light shielding walls 145 to 147 are disposed in a groove portions 142 to 144, respectively. The light shielding walls 155 to 157 are disposed in a groove portions 152 to 154, respectively. Note that the light shielding walls 145 to 147 are configured as continuous grooves, and the light shielding walls 155 to 157 are configured as continuous grooves. Thus, the light shielding walls 145 to 147 are configured to have a continuous wall shape, and the light shielding walls 155 to 157 are configured to have a continuous wall shape. On the back face of the semiconductor substrate 120, the groove portion 142 and the groove portion 154 are configured as continuous grooves, and the groove portion 144 and the groove portion 152 are configured as continuous grooves. On the other hand, the groove portions 142 to 144 and the groove portions 152 to 154 have different depths from the back face of the semiconductor substrate 120. In this manner, the pixel 100 has a shape surrounded by the grooves having the step.

Note that, as illustrated in FIG. 4, the semiconductor region 124 of the first charge holding unit 107 can be disposed in a region excluding the gate electrode 123 of the first charge transfer unit 102. As illustrated in FIG. 4, the charge holding unit light shielding film 140 and the charge transfer unit light shielding film 150 each are configured to have a band shape, are alternately disposed, and are configured to have a shape in which the vicinities of the respective end portions overlap each other. As a result, the entire face of the pixel 100 can be shielded from light in the light receiving face view. Therefore, as described above, the first charge holding unit 107 can be disposed in a wide range excluding the gate electrode 123.

Note that the groove portion 142 is an example of a first charge holding unit adjacent groove described in the claims. The light shielding wall 145 is an example of a first charge holding unit adjacent light shielding wall described in the claims. The groove portion 144 is an example of a second charge holding unit adjacent groove described in the claims. The light shielding wall 147 is an example of a second charge holding unit adjacent light shielding wall described in the claims. The groove portion 143 is an example of a third charge holding unit adjacent groove described in the claims. The light shielding wall 146 is an example of a third charge holding unit adjacent light shielding wall described in the claims. The groove portion 152 is an example of a first charge transfer unit adjacent groove described in the claims. The light shielding wall 155 is an example of a first charge transfer unit adjacent light shielding wall described in the claims. The groove portion 154 is an example of a second charge transfer unit adjacent groove described in the claims. The light shielding wall 157 is an example of a second charge transfer unit adjacent light shielding wall described in the claims. The groove portion 153 is an example of a third charge transfer unit adjacent groove described in the claims. The light shielding wall 156 is an example of a third charge transfer unit adjacent light shielding wall described in the claims.

### [Configuration of Groove Portion]

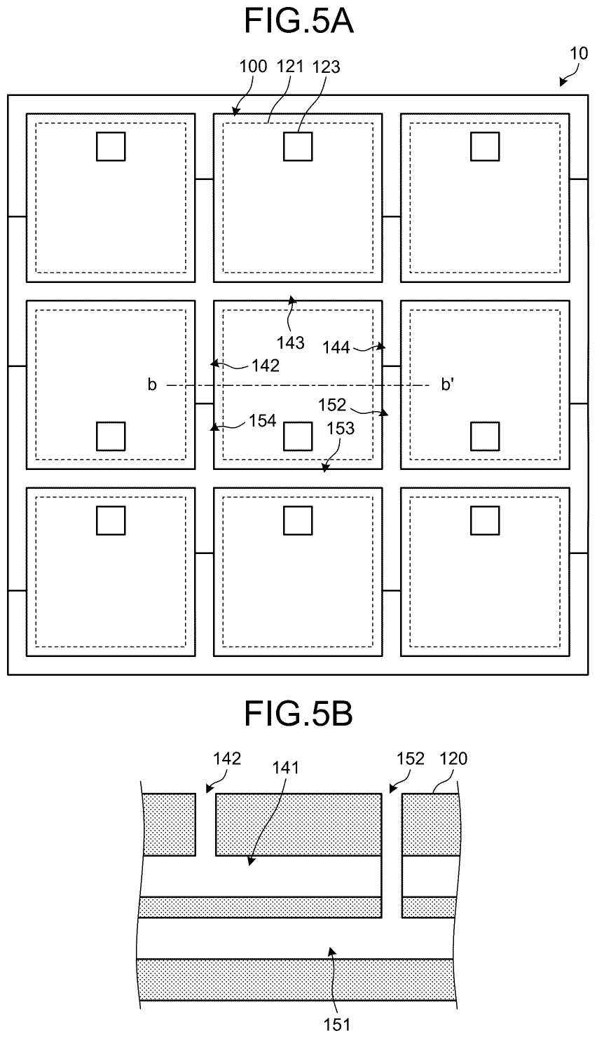

FIG. 5A is a plan view illustrating a configuration example of a groove portion according to the first embodiment of the present disclosure. FIG. 5A is a diagram illustrating a configuration example of the groove portions 142 to 144 and the groove portions 152 to 154. As in FIG. 4, FIG. 5A is a plan view of the pixel 100 viewed from the back face of the semiconductor substrate 120, and is a diagram illustrating the pixel 100 in a simplified manner. The groove portions 142 to 144 and the groove portions 152 to 154 can be configured to have a shape common to the adjacent pixels 100. FIG. 5A illustrates an example in which the groove portions 142 to 144 and the groove portions 152 to 154 are configured to have a common shape in two vertically adjacent pixels 100. The groove portion 143 is common to the upper and lower pixels 100. The groove portions 142 and 144 are configured to have a shape coupled to the upper and lower pixels 100. The groove portions 152 to 154 can be configured to have the same shape as the groove portions 142 to 144.

FIG. 5B is a cross-sectional view illustrating a configuration example of the groove portion according to the first embodiment of the present disclosure. FIG. 5B is a cross-sectional view taken along line b-b′ of FIG. 5A, and is a diagram illustrating a configuration example of the groove portions 142 and 152, the charge holding unit adjacent gap 141, and the charge transfer unit adjacent gap 151. The bottom portion of the groove portion 142 is coupled to the charge holding unit adjacent gap 141. Further, the bottom portion of the groove portion 152 is coupled to the charge transfer unit adjacent gap 151. The charge holding unit adjacent gap 141 can be formed by etching the inside of the semiconductor substrate 120 in the direction of the band of the charge holding unit light shielding film 140 with the bottom portion of the groove portion 142 as a starting point. Similarly, the charge transfer unit adjacent gap 151 can be formed by etching the inside of the semiconductor substrate 120 in the direction of the band of the charge transfer unit light shielding film 150 with the bottom portion of the groove portion 152 as a starting point.

### [Method of Manufacturing Charge Holding Unit Adjacent Gap]

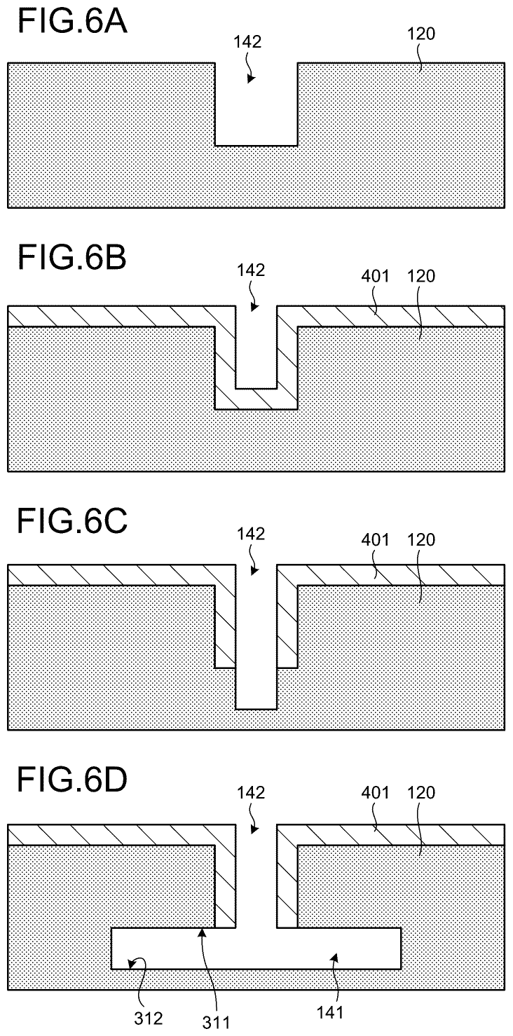

FIGS. 6A to 6D are diagrams illustrating an example of a method of manufacturing the charge holding unit adjacent gap according to the first embodiment of the present disclosure. FIGS. 6A to 6D are diagrams illustrating an example of a process of manufacturing the charge holding unit light shielding film 140.

First, the back face of the semiconductor substrate 120 is etched to form the groove portion 142 (FIG. 6A). This can be formed, for example, by disposing a hard mask having an opening in a region where the groove portion 142 is formed on the back face of the semiconductor substrate 120 and performing dry etching. At this time, the groove portion 142 is formed in a direction along the crystal orientation <112> of the semiconductor substrate 120. In FIG. 6A, a direction perpendicular to the paper face is a direction along the crystal orientation <112>.

Next, an insulating film 401 is disposed on the back face of the semiconductor substrate 120 including the groove portion 142 (FIG. 6B). The insulating film 401 can be formed of a film of silicon nitride (SiN) or SiO₂.

Next, the insulating film 401 at the bottom portion of the groove portion 142 is removed, and the semiconductor substrate 120 at the bottom portion of the groove portion 142 is etched to deepen the groove portion 142 (FIG. 6C). This can be performed by etching back of dry etching. Through this step, the face of the semiconductor substrate 120 can be exposed in the vicinity of the bottom portion of the groove portion 142.

Next, the bottom portion of the groove portion 142 is etched using the insulating film 401 as a mask (FIG. 6D). This etching can be performed by wet etching using a chemical solution. As the chemical solution used for the wet etching, a chemical solution having different etching rates according to the plane direction of the semiconductor substrate 120 is used. Specifically, a chemical solution in which the etching rate in the direction of the crystal orientation <110> is higher than that in the direction of the crystal orientation <111> is used. Examples of the chemical solution can include potassium hydroxide (KOH), sodium hydroxide (NaOH), cesium hydroxide (CsOH), hydrazine (N₂H₄), and ammonium hydroxide (NH₄OH). In addition, an organic solution such as an ethylenediamine pyrocatechol aqueous solution (EDP) or tetramethylammonium hydroxide (TMAH) can also be used. As illustrated in FIG. 6D, etching proceeds in the direction of the crystal orientation <110>, and the charge holding unit adjacent gap 141 can be formed. As will be described later, by forming the groove portion 142 in the direction along the crystal orientation <112>, the wall face of the groove portion 142 can be etched in the direction of the crystal orientation <110>. Note that the upper face and the lower face of the charge holding unit adjacent gap 141 are faces of the plane direction (111), and are hardly etched.

Through the above steps, the charge holding unit adjacent gap 141 can be formed. Note that the charge transfer unit adjacent gap 151 can also be formed by a similar process.

### [Etching of Charge Holding Unit Adjacent Gap]

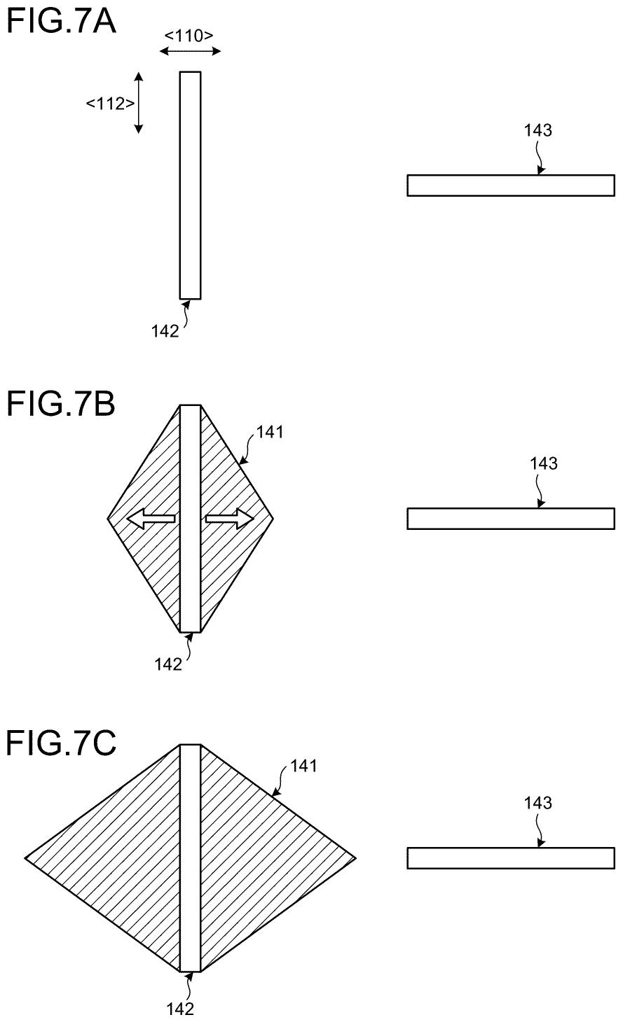

FIGS. 7A to 7C are diagrams illustrating an example of a method of etching a charge holding unit adjacent gap according to the first embodiment of the present disclosure. FIGS. 7A to 7C are views for explaining an etching method of the charge holding unit adjacent gap 141, and illustrate the groove portion 142 and the like when viewed from the back face of the semiconductor substrate 120.

In FIG. 7A, the groove portion 142 is formed on the back face of the semiconductor substrate 120. As illustrated in FIG. 7A, the lateral direction of the paper is the direction of the crystal orientation <110>, and the longitudinal direction of the paper is the direction of the crystal orientation <112>. As described above, the groove portion 142 is formed in a direction along the crystal orientation <112>. In FIG. 7A, the groove portion 143 is described as a comparative example. The groove portion 143 is formed in a direction orthogonal to the groove portion 142 and is formed in a direction along the crystal orientation <110>.

In FIG. 7B, wet etching is started. Formation of the charge holding unit adjacent gap 141 is started at the bottom portion of the groove portion 142. As described above, the etching proceeds in the direction of the crystal orientation <110>. In the initial stage of etching, the semiconductor substrate 120 is etched into a triangular shape in which the central portion protrudes as illustrated in FIG. 7B. A white arrow in FIG. 7B indicates a direction in which etching proceeds. A face having a plane direction (111) appears by etching on an etched face corresponding to a side from the central portion of the triangle to the end portion of the groove portion 142. On the other hand, since the etching is hardly performed in the direction of the crystal orientation <112>, the etching of the bottom portion of the groove portion 143 does not proceed.

In FIG. 7C, etching of the bottom portion of the groove portion 142 further proceeds, and a face having the next plane direction (111) appears on the etched face. As described above, by forming the groove portion 142 in the direction along the crystal orientation <112>, the semiconductor substrate 120 can be etched in the direction perpendicular to the groove portion 142.

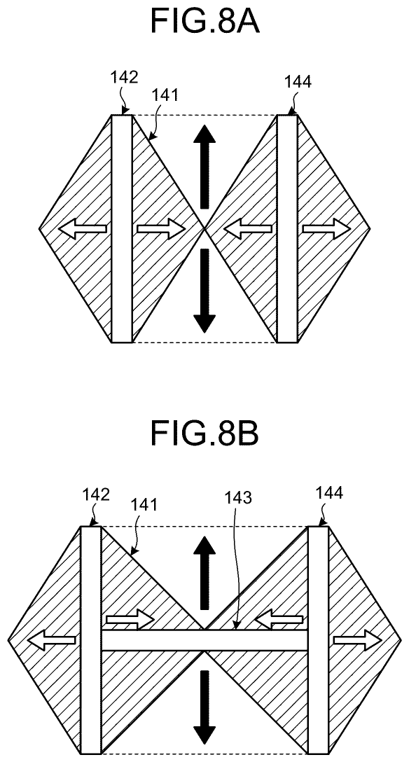

FIGS. 8A and 8B are diagrams illustrating another example of the method of etching the charge holding unit adjacent gap according to the first embodiment of the present disclosure. FIGS. 8A and 8B are diagrams for explaining etching of the charge holding unit adjacent gap 141 in a case where the groove portion 142 and the groove portion 144 are used. For convenience, the groove portions 142 and 144 have the same length.

As illustrated in FIG. 8A, when the groove portion 142 and the groove portion 144 disposed side by side are etched, the etching simultaneously proceeds in the groove portion 142 and the groove portion 144, and the charge holding unit adjacent gap 141 having a triangular shape is formed. When the etching proceeds and the central portions of the triangles are connected to each other, the etching proceeds in the direction of the crystal orientation <112>. A black arrow in FIG. 8A indicates a direction in which the etching proceeds at this time. The etching in the direction of the crystal orientation <112> proceeds to a position indicated by a broken line in FIG. 8A. As a result, the band-shaped charge holding unit adjacent gap 141 can be formed.

As illustrated in FIG. 8B, when the groove portion 143 is disposed between the groove portion 142 and the groove portion 144 disposed side by side, the etching of the charge holding unit adjacent gap 141 having a triangular shape can be promoted. By disposing the groove portion 143, even in a case where the groove portion 142 and the groove portion 144 are disposed away from each other, it is possible to shorten the formation time of the band-shaped charge holding unit adjacent gap 141.

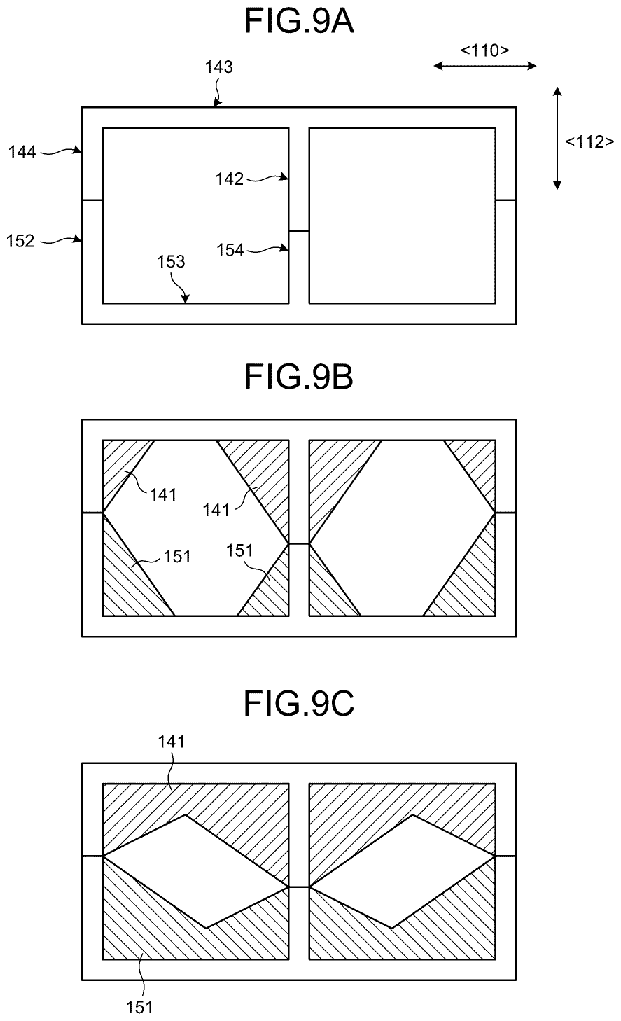

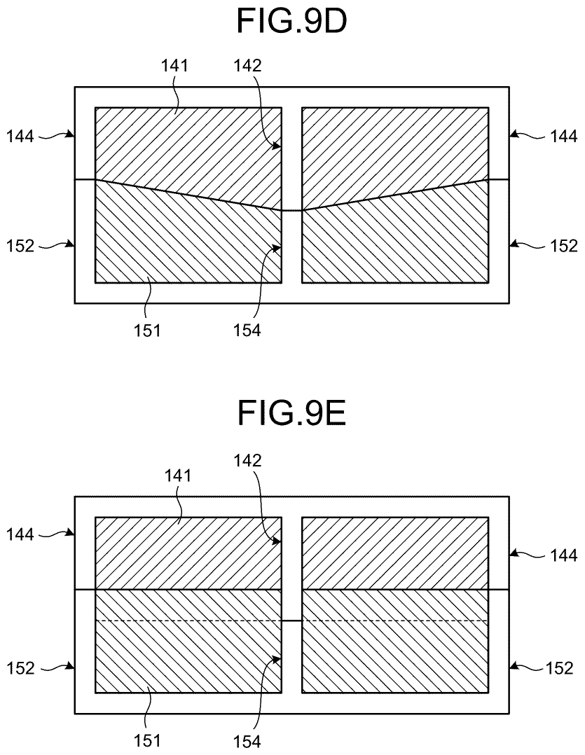

FIGS. 9A to 9E are diagrams illustrating an example of a method of forming a charge holding unit adjacent gap and a charge transfer unit adjacent gap according to the first embodiment of the present disclosure. FIGS. 9A to 9E are diagrams for explaining a method of forming the charge holding unit adjacent gap 141 and the charge transfer unit adjacent gap 151.

In FIG. 9A, the groove portions 142 to 144 and the groove portions 152 to 154 are formed. The groove portions 142, 144, 152, and 154 are formed in the direction of the crystal orientation <112>. The groove portions 143 and 153 are formed in the direction of the crystal orientation <110>.

In FIG. 9B, wet etching is started. The charge holding unit adjacent gap 141 having a triangular shape is formed on the longitudinal faces of the groove portions 142 and 144. The charge transfer unit adjacent gap 151 having a triangular shape is formed on the longitudinal faces of the groove portions 152 and 154.

In FIG. 9C, the etching proceeds, and the two charge holding unit adjacent gaps 141 each having a triangular shape are connected, and the two charge transfer unit adjacent gaps 151 each having a triangular shape are connected.

In FIG. 9D, the etching further proceeds, and the charge holding unit adjacent gap 141 having a shape connecting the end portions of the groove portions 142 and 144 is formed. Similarly, the charge transfer unit adjacent gap 151 having a shape connecting the end portions of the groove portions 152 and 154 is formed.

In FIG. 9E, the etching further proceeds, and the charge transfer unit adjacent gap 151 having a shape connecting the end portions of the two groove portions 152 at the boundary between the adjacent pixels 100 is formed. In addition, the charge holding unit adjacent gap 141 having a shape connecting the end portions of the two groove portions 142 is formed. A broken line in FIG. 9E represents an end portion of the charge holding unit adjacent gap 141. It is possible to form the charge holding unit adjacent gap 141 and the charge transfer unit adjacent gap 151 having shapes in which the end portions overlap each other.

As described above, by disposing the groove portion 142 having a length reaching the end portion of the charge holding unit adjacent gap 141 and the groove portion 152 having a length reaching the end portion of the charge transfer unit adjacent gap 151 on opposite sides of the pixel 100, the charge holding unit adjacent gap 141 and the charge transfer unit adjacent gap 151 can be configured to have widths in which the end portions overlap each other. Even when the groove portion 142 and the groove portion 152 are disposed on the same side face of the semiconductor substrate 120, the charge holding unit adjacent gap 141 and the charge transfer unit adjacent gap 151 having widths in which the end portions overlap each other can be disposed.

Note that the groove portions 142 to 144 and the groove portions 152 to 154 are preferably formed toward the back face of the semiconductor substrate 120. This is because the arrangement of the first charge transfer unit 102 and the like toward the front face of the semiconductor substrate 120 is facilitated.

### [Method of Manufacturing Imaging Element]

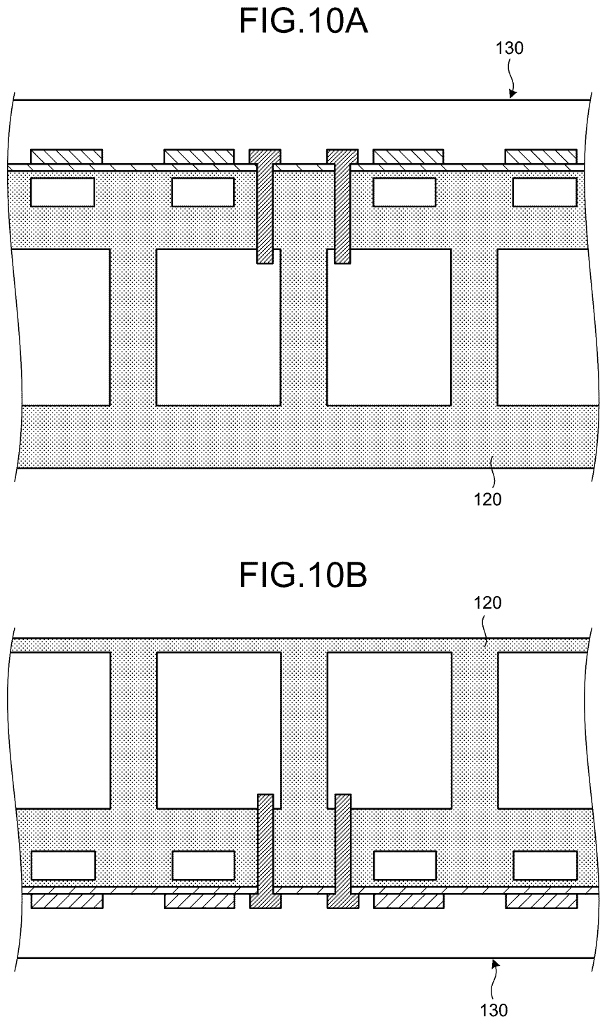

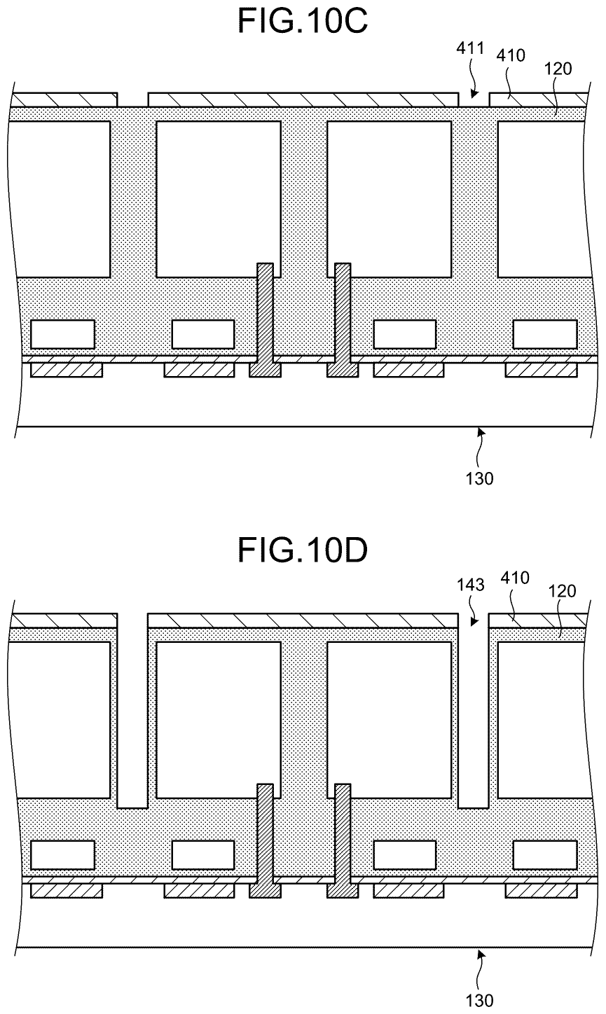

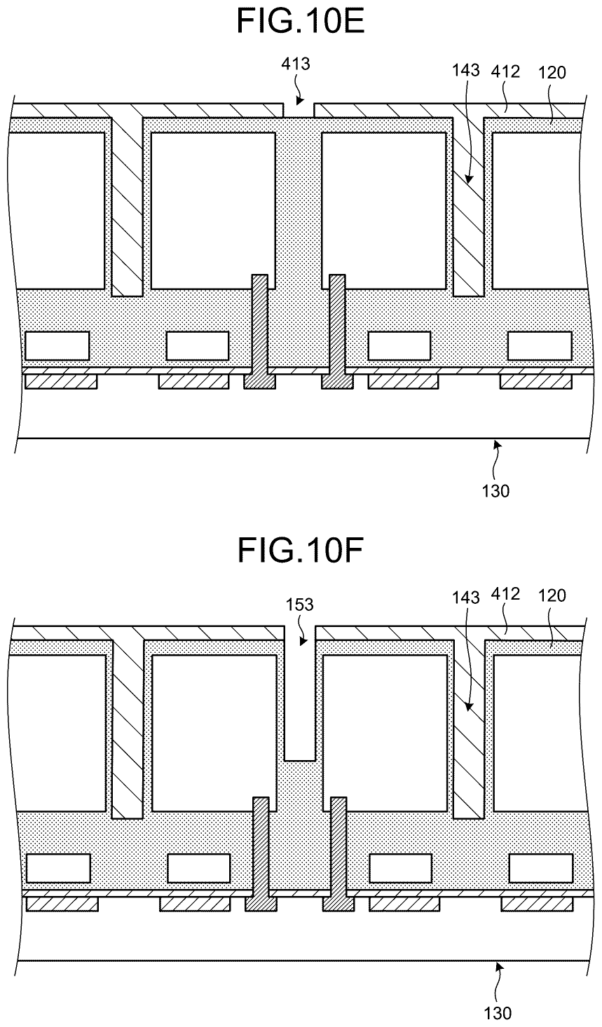

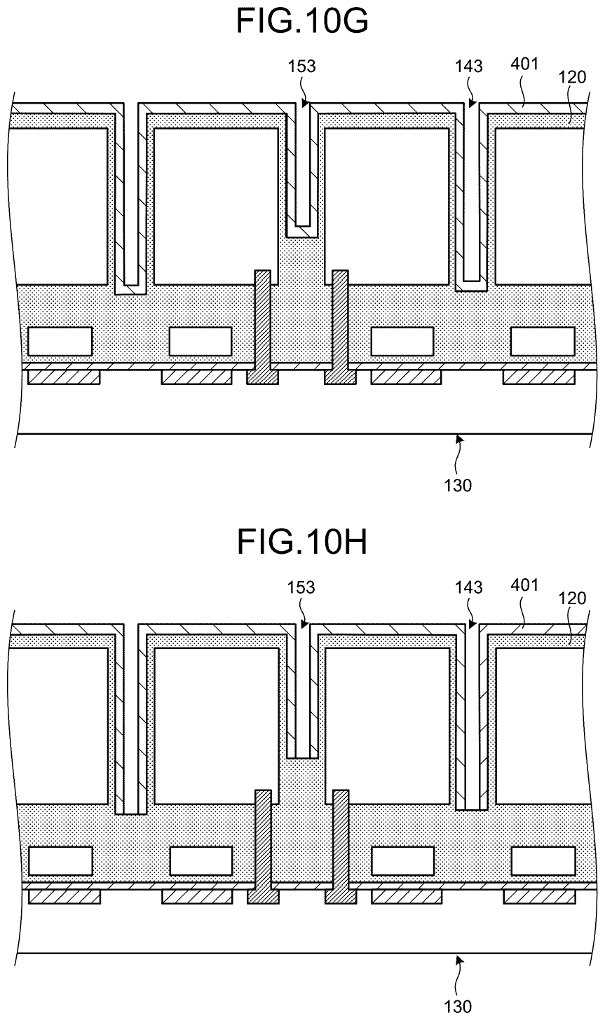

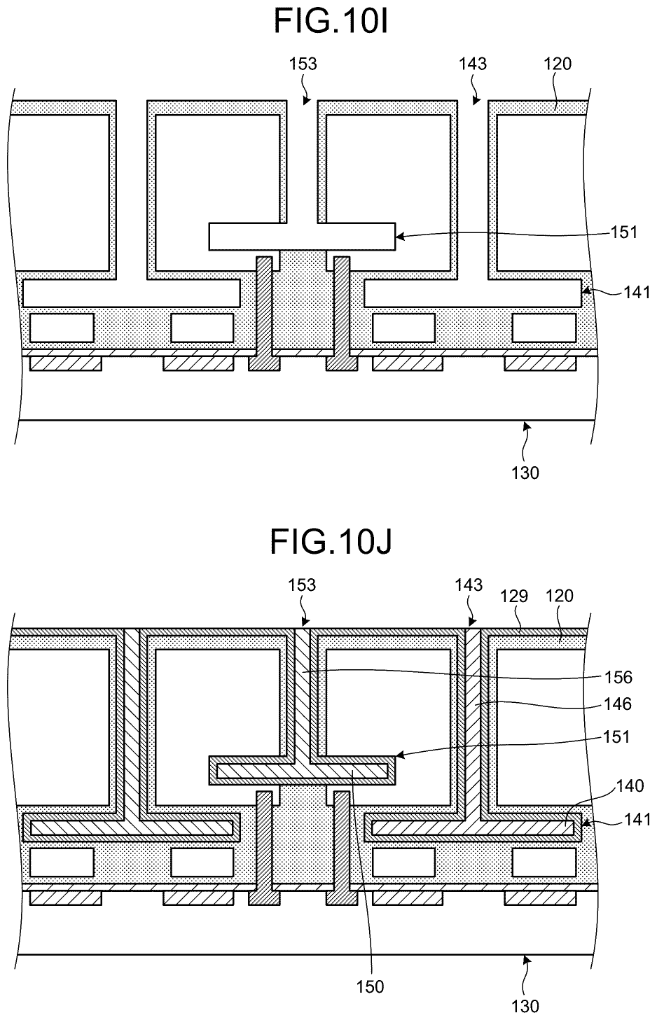

FIGS. 10A to 10J are diagrams illustrating an example of a method of manufacturing the imaging element according to the first embodiment of the present disclosure. FIGS. 10A to 10J are diagrams illustrating an example of a process of manufacturing the imaging element 1. For convenience, the configuration of the pixel 100 has been simplified.

First, a well region is formed in the semiconductor substrate 120, and the semiconductor region 121 and the like of the photoelectric conversion unit 101 are formed. Next, the gate electrodes 123 and 125 are formed. Thus, the pixel 100 is formed. At this time, the photoelectric conversion unit 101 is configured to have a substantially rectangular shape on the surface of the semiconductor substrate 120, and the pixel 100 is configured to have a rectangular shape (FIG. 10A). The step is an example of a step of forming a pixel described in the claims.

Next, the wiring region 130 is formed on the front face of the semiconductor substrate 120. Next, the semiconductor substrate 120 is turned upside down, and the back face of the semiconductor substrate 120 is ground to be thinned (FIG. 10B).

Next, a hard mask 410 is disposed on the back face of the semiconductor substrate 120. In the hard mask 410, an opening 411 is disposed in a region where the groove portions 142 to 144 are disposed (FIG. 10C).

Next, the semiconductor substrate 120 is etched using the hard mask 410 as a mask. Dry etching can be applied to this etching. Thus, the groove portions 142 to 144 are formed (FIG. 10D). Note that the groove portion 143 is illustrated in FIG. 10D. Next, the hard mask 410 is removed.

Next, a hard mask 412 is disposed on the back face of the semiconductor substrate 120 including the groove portions 142 to 144. In the hard mask 412, an opening 413 is disposed in a region where the groove portions 152 to 154 are formed (FIG. 10E).

Next, etching is performed on the back face of the semiconductor substrate 120 using the hard mask 412 as a mask to form the groove portions 152 to 154 (FIG. 10F). Note that the groove portion 153 is illustrated in FIG. 10F. Next, the hard mask 412 is removed.

Next, the insulating film 401 is disposed on the back face of the semiconductor substrate 120 including the groove portions 142 to 144 and the groove portions 152 to 154. This can be performed, for example, by chemical vapor deposition (CVD) (FIG. 10G).

Next, the insulating film 401 on the bottom faces of the groove portions 142 to 144 and the groove portions 152 to 154 is removed. This can be done by etch back using dry etching (FIG. 10H).

Next, the steps described in FIGS. 6C and 6D are executed to form the charge holding unit adjacent gap 141 and the charge transfer unit adjacent gap 151 (FIG. 10I).

Next, the insulating film 129 is disposed on the back face of the semiconductor substrate 120 including the groove portions 142 to 144, the groove portions 152 to 154, the charge holding unit adjacent gap 141, and the charge transfer unit adjacent gap 151. Next, light shielding members are disposed in the groove portions 142 to 144, the groove portions 152 to 154, the charge holding unit adjacent gap 141, and the charge transfer unit adjacent gap 151 (FIG. 10J). This can be performed, for example, by disposing a light shielding member such as tungsten (W) in the charge holding unit adjacent gap 141 or the like using CVD. As a result, the charge holding unit light shielding film 140, the charge transfer unit light shielding film 150, the light shielding walls 145 to 147, and the light shielding walls 155 to 157 can be simultaneously formed. The step is an example of a step of forming a charge holding unit light shielding film and a step of forming a charge transfer unit light shielding film described in the claims.

Thereafter, the planarizing film 171, the color filter 172, and the on-chip lens 173 are disposed. The imaging element 1 can be manufactured by the above steps.

As described above, in the imaging element 1 according to the first embodiment of the present disclosure, the charge holding unit light shielding film 140 and the charge transfer unit light shielding film 150 having a band shape in which the vicinities of the end portions overlap each other are disposed in the semiconductor substrate 120 to shield incident light. As a result, leakage of incident light to the first charge holding unit 107 can be reduced in the pixel 100 configured to have a shape in which the photoelectric conversion unit 101 and the first charge holding unit 107 overlap each other in light receiving face view. Noise of the image signal can be reduced.

### 2. Second Embodiment

In the imaging element 1 of the first embodiment described above, the light shielding walls 145 and 147 and the light shielding wall 146 are coupled, and the light shielding walls 155 and 157 and the light shielding wall 156 are coupled. On the other hand, the imaging element 1 according to the second embodiment of the present disclosure is different from that according to the above-described first embodiment in that the light shielding walls 145 and 147 and the light shielding wall 146 are separated, and the light shielding walls 155 and 157 and the light shielding wall 156 are separated.

### [Configuration of Groove Portion]

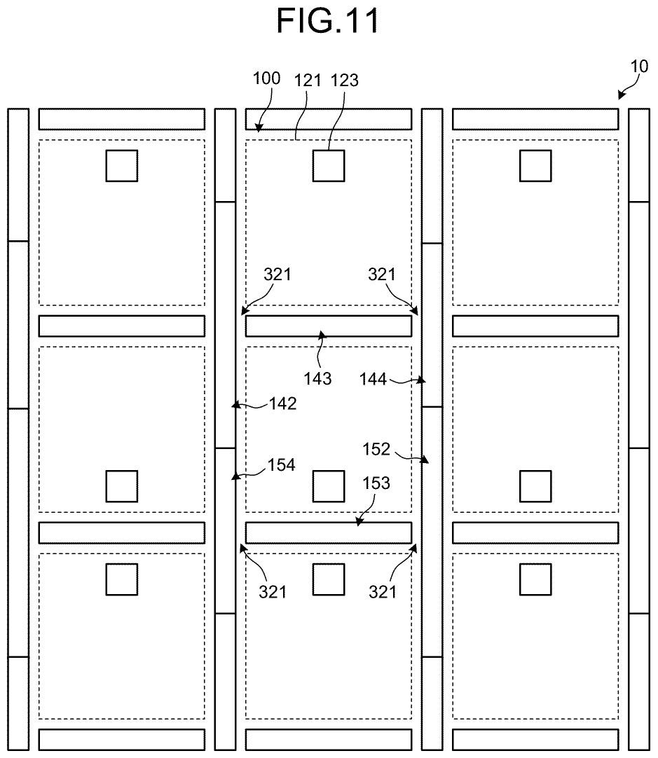

FIG. 11 is a plan view illustrating a configuration example of a groove portion according to the second embodiment of the present disclosure. FIG. 11 is a diagram illustrating configuration examples of the groove portions 142 to 144 and the groove portions 152 to 154 in the pixel 100, as in FIG. 5A. The pixel 100 in FIG. 11 is different from the pixel 100 in FIG. 5A in that a semiconductor region 321 is disposed between the groove portions 142 and 144, and the groove portion 143, and the semiconductor region 321 is disposed between the groove portions 152 and 154, and the groove portion 153.

In the pixel 100 in FIG. 11, the groove portions 142 and 144 are not connected to the groove portion 143. Similarly, the groove portions 152 and 154 are not connected to the groove portion 153. By disposing the light shielding member in the groove portions 142 to 144 and the groove portions 152 to 154, the light shielding walls 145 and 147, and the light shielding wall 146 can be separated, and the light shielding walls 155 and 157, and the light shielding wall 156 can be separated. Since the semiconductor region 321 is disposed between the groove portions 142 and 144, and the groove portion 143, it is possible to prevent the occurrence of the microloading phenomenon in the region. Similarly, since the semiconductor region 321 is disposed between the groove portions 152 and 154, and the groove portion 153, it is possible to prevent the occurrence of the microloading phenomenon in this region.

Here, the microloading phenomenon is a phenomenon in which the etching rate changes according to the density of the etching pattern and the etching depth changes. In a case where the groove portions 142 and 144, and the groove portion 143 are coupled, the etching rate of the coupling portion increases, and the groove of the coupling portion is deep. Therefore, the depth of the charge holding unit adjacent gap 141 in the region changes, and the charge holding unit light shielding film 140 is deformed. A similar problem occurs in the charge transfer unit adjacent gap 151.

The configuration of the imaging element 1 other than this is similar to the configuration of the imaging element 1 in the first embodiment of the present disclosure, and thus description thereof is omitted.

As described above, in the imaging element 1 according to the second embodiment of the present disclosure, the semiconductor region 321 is disposed between the groove portions 142 and 144, and the groove portion 143, and the semiconductor region 321 is disposed between the groove portions 152 and 154, and the groove portion 153. As a result, it is possible to prevent the occurrence of a microloading phenomenon, and it is possible to prevent deformation of the charge holding unit light shielding film 140 and the charge transfer unit light shielding film 150.

### 3. Third Embodiment

In the imaging element 1 of the first embodiment described above, the light shielding walls 145 to 147, and the light shielding walls 155 to 157 are disposed. On the other hand, the imaging element 1 according to the third embodiment of the present disclosure is different from that according to the above-described first embodiment in that light shielding walls 145 and 155 are omitted.

### [Configuration of Groove Portion]

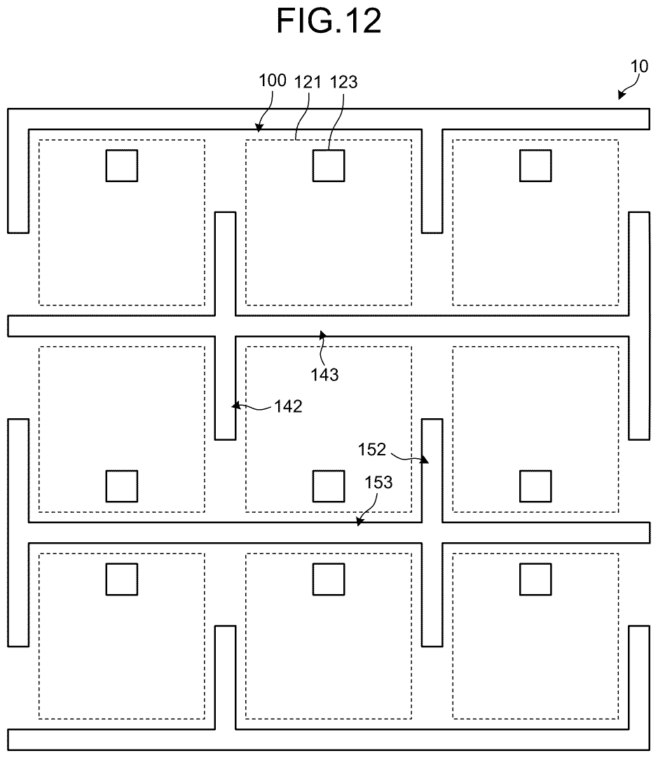

FIG. 12 is a plan view illustrating a configuration example of a groove portion according to the third embodiment of the present disclosure. FIG. 12 is a diagram illustrating a configuration example of the groove portion 142 and the like in the pixel 100, as in FIG. 5A. The pixel 100 in FIG. 12 is different from the pixel 100 in FIG. 5A in that the groove portions 144 and 154, and the light shielding walls 145 and 155 disposed in these groove portions are omitted.

Even in a case where the groove portions 144 and 154 are omitted, the charge holding unit adjacent gap 141 can be formed by the two groove portions 142 in the adjacent pixel 100. Furthermore, the charge transfer unit adjacent gap 151 can be formed by the two groove portions 152 in the adjacent pixels 100.

### [Modifications]

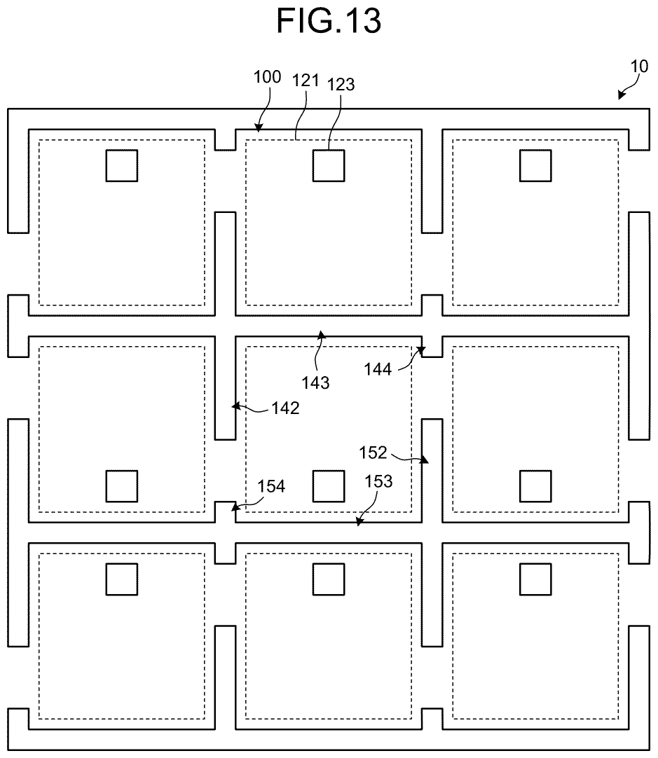

FIG. 13 is a plan view illustrating a configuration example of a groove portion according to a modification of the third embodiment of the present disclosure. FIG. 13 is a diagram illustrating a configuration example of the groove portion 142 and the like in the pixel 100, as in FIG. 12. The pixel 100 in FIG. 13 is different from the pixel 100 in FIG. 12 in that short groove portions 144 and 154 are disposed.

The configuration of the imaging element 1 other than this is similar to the configuration of the imaging element 1 in the first embodiment of the present disclosure, and thus description thereof is omitted.

### 4. Fourth Embodiment

In the imaging element 1 of the first embodiment described above, the first charge holding unit 107 is shielded from light by the charge holding unit light shielding film 140. On the other hand, the imaging element 1 according to the fourth embodiment of the present disclosure is different from that according to the above-described first embodiment in that a light shielding film having a depth different from that of the charge holding unit light shielding film 140 is further used.

### [Configuration of Pixel]

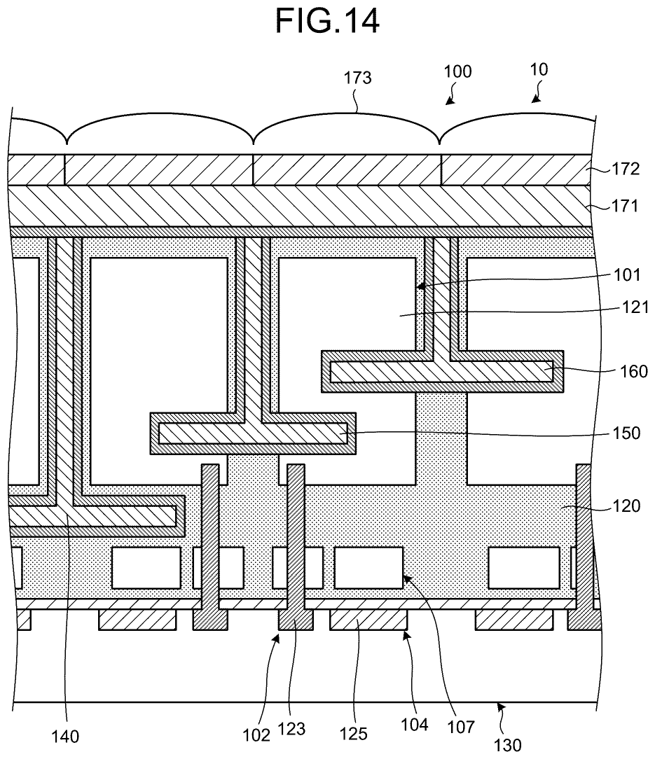

FIG. 14 is a cross-sectional view illustrating a configuration example of a pixel according to the fourth embodiment of the present disclosure. FIG. 14 is a cross-sectional view illustrating a configuration example of the pixel 100 as in FIG. 3. The pixel 100 in FIG. 14 is different from the pixel 100 in FIG. 3 in that it further includes a charge holding unit light shielding film 160.

The charge holding unit light shielding film 160 in FIG. 14 shields incident light as in the charge holding unit light shielding film 140. The charge holding unit light shielding film 160 is configured to have a shape that covers the first charge holding unit 107 in a light receiving face view, and is disposed at a position shallower than the charge holding unit light shielding film 140. The imaging element 1 in FIG. 14 illustrates an example in which the charge holding unit light shielding film 140 and the charge holding unit light shielding film 160 are alternately disposed in the adjacent pixels 100.

The configuration of the imaging element 1 other than this is similar to the configuration of the imaging element 1 in the first embodiment of the present disclosure, and thus description thereof is omitted.

### 5. Fifth Embodiment

In the imaging element 1 of the first embodiment described above, the charge holding unit adjacent gap 141 and the charge transfer unit adjacent gap 151 are formed by the groove portion formed toward the back face of the semiconductor substrate 120, and the charge holding unit light shielding film 140 and the charge transfer unit light shielding film 150 are disposed. On the other hand, the imaging element 1 according to the fifth embodiment of the present disclosure is different from that according to the above-described first embodiment in that a charge holding unit adjacent gap and a charge transfer unit adjacent gap are formed from the front face of the semiconductor substrate 120.

### [Configuration of Pixel]

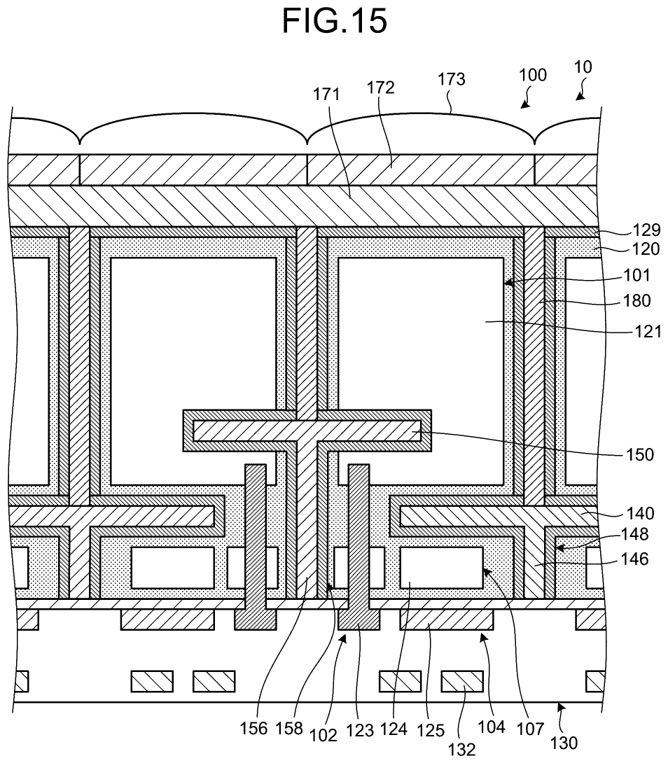

FIG. 15 is a cross-sectional view illustrating a configuration example of a pixel according to the fifth embodiment of the present disclosure. FIG. 15 is a cross-sectional view illustrating a configuration example of the pixel 100 as in FIG. 3. The pixel 100 in FIG. 15 is different from the pixel 100 in FIG. 3 in that it includes the charge holding unit light shielding film 140 and the charge transfer unit light shielding film 150 formed from the front face of the semiconductor substrate 120.

The charge holding unit light shielding film 140 in FIG. 15 is disposed in a charge holding unit adjacent gap formed with a groove portion 148 disposed toward the front face of the semiconductor substrate 120 as a starting point. Furthermore, the charge transfer unit light shielding film 150 in FIG. 15 is disposed in a charge transfer unit adjacent gap formed with a groove portion 158 disposed toward the front face of the semiconductor substrate 120 as a starting point. The light shielding walls 146 and 156 are disposed in the groove portion 148 and the groove portion 158, respectively. Note that a light shielding wall 180 is disposed on the semiconductor substrate 120 at the boundary of the pixels 100, and shields incident light obliquely incident from the adjacent pixel 100.

The configuration of the imaging element 1 other than this is similar to the configuration of the imaging element 1 in the first embodiment of the present disclosure, and thus description thereof is omitted.

### 6. Modification

A modification of the imaging element 1 will be described.

### [Configuration of Groove Portion]

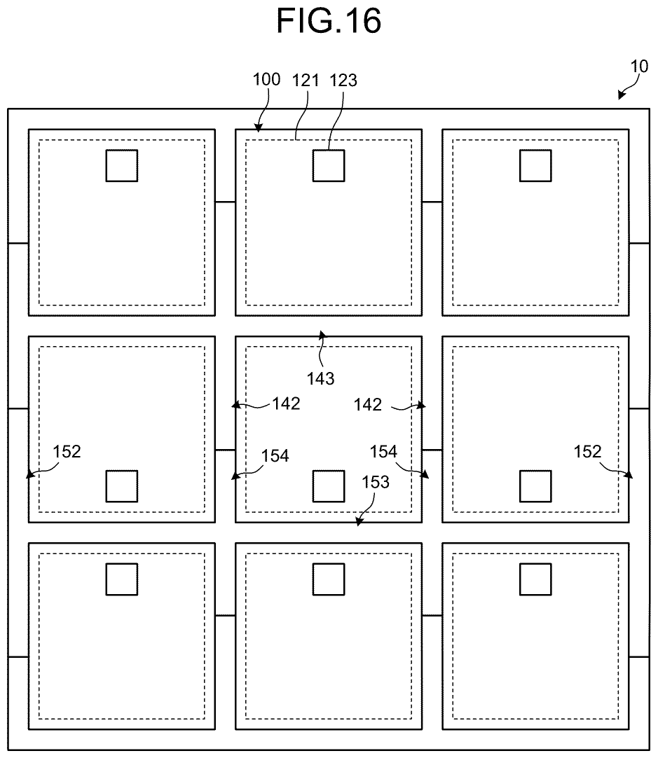

FIG. 16 is a plan view illustrating a configuration example of a groove portion according to a modification of the embodiment of the present disclosure. FIG. 16 is a diagram illustrating exemplary configurations of the groove portions 142 to 144 and the groove portions 152 to 154, as in FIG. 5A. The pixel 100 FIG. 16 is different from the pixel 100 in FIG. 5A in that the arrangement of the groove portion is changed for each pixel 100.

In the pixel 100 at the center in FIG. 16, two groove portions 142 and two groove portions 154 are disposed. That is, in the pixel 100 in the center of FIG. 16, the groove portion 152 having a length reaching the end portion of the charge transfer unit light shielding film 150 for forming the charge transfer unit adjacent gap 151 is not disposed. Even in this case, the charge transfer unit adjacent gap 151 can be formed by the groove portions 152 of the pixels 100 adjacent on the left and right sides.

### [Configuration of First Charge Transfer Unit]

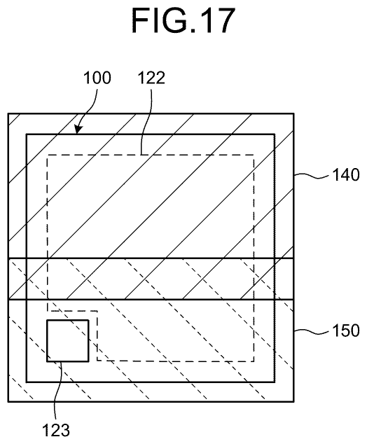

FIG. 17 is a plan view illustrating a configuration example of a first charge holding unit according to a modification of the embodiment of the present disclosure. FIG. 17 is a diagram illustrating an arrangement example of the gate electrode 123 of the first charge holding unit 107. The gate electrode 123 in FIG. 17 is disposed at a corner of the pixel 100 in the light receiving face view. In this manner, the first charge holding unit 107 can be disposed at an any position light shielded by the charge transfer unit light shielding film 150.

### 7. Configuration of Imaging Device

The technology according to the present disclosure can be applied to various products. For example, the technology according to the present disclosure can be applied to an imaging device such as a camera.

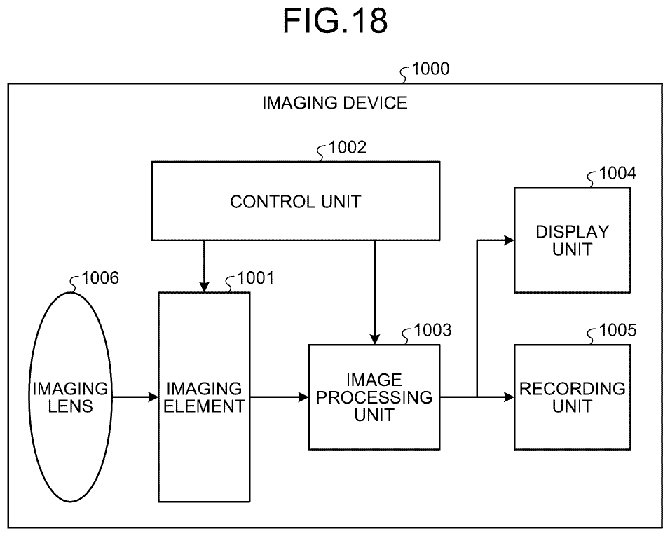

FIG. 18 is a diagram illustrating a configuration example of an imaging device to which the technology according to the present disclosure can be applied. An imaging device 1000 in FIG. 18 includes an imaging element 1001, a control unit 1002, an image processing unit 1003, a display unit 1004, a recording unit 1005, and an imaging lens 1006.

The imaging lens 1006 is a lens that collects light from a subject. The subject is imaged on the light receiving face of the imaging element 1001 by the imaging lens 1006.

The imaging element 1001 is an element that images a subject. A plurality of pixels including a photoelectric conversion unit that performs photoelectric conversion of light from a subject is disposed on a light receiving face of the imaging element 1001. Each of the plurality of pixels generates an image signal based on a charge generated by photoelectric conversion. The imaging element 1001 converts an image signal generated by the pixel into a digital image signal to output the digital image signal to the image processing unit 1003. Note that image signals for one screen are referred to as a frame. The imaging element 1001 can also output an image signal in frame.

The control unit 1002 controls the imaging element 1001 and the image processing unit 1003. The control unit 1002 can be configured by, for example, an electronic circuit using a microcomputer or the like.

The image processing unit 1003 processes an image signal from the imaging element 1001. The processing of the image signal in the image processing unit 1003 corresponds to, for example, demosaic processing of generating an image signal of a color that is insufficient when a color image is generated or noise reduction processing of removing noise of the image signal. The image processing unit 1003 can be configured by, for example, an electronic circuit using a microcomputer or the like.

The display unit 1004 displays an image based on the image signal processed by the image processing unit 1003. The display unit 1004 can be configured by, for example, a liquid crystal monitor.

The recording unit 1005 records an image (frame) based on the image signal processed by the image processing unit 1003. The recording unit 1005 can be configured by, for example, a hard disk or a semiconductor memory.

The imaging device to which the present disclosure can be applied is described above. The present technology can be applied to the imaging element 1001 among the above-described components. Specifically, the imaging element 1 described in FIG. 1 can be applied to the imaging element 1001. Note that the image processing unit 1003 is an example of a processing circuit described in the claims. The imaging device 1000 is an example of an imaging device described in the claims.

Note that the configuration of the second embodiment of the present disclosure can be applied to other embodiments. Specifically, the groove portion 143 and the groove portion 153 in FIG. 11 can be applied to the third to fifth embodiments of the present disclosure.

### Effects

The imaging element 1 of the present disclosure includes the pixel 100, the charge holding unit light shielding film 140, and the charge transfer unit light shielding film 150. The pixel 100 includes the photoelectric conversion unit 101 that is disposed on the light receiving face of the semiconductor substrate 120 and performs photoelectric conversion on incident light, the first charge holding unit 107 that is disposed on a side different from a side of the light receiving face of the semiconductor substrate 120 and holds a charge generated by the photoelectric conversion, and the first charge transfer unit 102 that transfers the generated charge to the first charge holding unit 107, and is configured to have a rectangular shape in a light receiving face view. The charge holding unit light shielding film 140 is configured to have a band shape adjacent to three sides including a first side that is one of the sides of the rectangle and parallel to the first side in a light receiving face view, is adjacent to a semiconductor region (region 127) including the first charge transfer unit 102 in a light receiving face view, and is disposed in the pixel 100 between the photoelectric conversion unit and the first charge holding unit 107 to shield incident light. The charge transfer unit light shielding film 150 is configured to have a band shape adjacent to three sides including a second side that is a side facing the first side in a light receiving face view and parallel to the second side, and is configured to have a shape disposed in the pixel 100 between the photoelectric conversion unit and the first charge transfer unit 102 to shield incident light and have an end portion overlapping an end portion of the charge holding unit light shielding film 140 in a light receiving face view. Thus, the first charge holding unit 107 can be shielded from light.

Furthermore, the semiconductor substrate 120 may have a face of a plane direction (111) orthogonal to a thickness direction, where a face opposite the face constitutes the light receiving face, in which the charge holding unit light shielding film 140 may include a light shielding member disposed in the charge holding unit adjacent gap 141 that is a gap formed by etching the semiconductor substrate 120 in a direction of a crystal orientation <110>, and the charge transfer unit light shielding film 150 may include a light shielding member disposed in a charge transfer unit adjacent gap 151 that is a gap formed by etching the semiconductor substrate 120 in a direction of the crystal orientation <110>. As a result, the charge holding unit light shielding film 140 and the charge transfer unit light shielding film 150 can be embedded in the semiconductor substrate 120.

Furthermore, the imaging element may further include the groove portion 142 that is a groove disposed on one of sides adjacent to the first side at a boundary of the pixel 100, configured to be parallel to a crystal orientation <112>, and configured to have a length reaching a vicinity of an end portion of the charge holding unit light shielding film 140 from the first side, and the groove portion 152 that is a groove disposed on a side facing a side on which the groove portion 142 is disposed at a boundary of the pixel 100, configured to be parallel to the crystal orientation <112>, and configured to have a length reaching a vicinity of an end portion of the charge transfer unit light shielding film 150 from the second side, in which the charge holding unit adjacent gap 141 may be formed by etching the semiconductor substrate 120 in a vicinity of a bottom portion of the groove portion 142 in a direction of the crystal orientation <110>, and the charge transfer unit adjacent gap 151 may be formed by etching the semiconductor substrate 120 in a vicinity of a bottom portion of the groove portion 152 in a direction of the crystal orientation <110>. Thus, a gap can be formed inside the semiconductor substrate 120.

Furthermore, the light shielding wall 145 that is disposed in the groove portion 142 and shields incident light may be further included. This makes it possible to shield light obliquely incident from the adjacent pixels 100.

Furthermore, the light shielding wall 155 that is disposed in the groove portion 152 and shields incident light may be further included. It is possible to shield light obliquely incident from the adjacent pixels 100.

Furthermore, the groove portion 142 may be formed on a same face of the semiconductor substrate 120 as the face on which the groove portion 152 is formed. As a result, the manufacturing process of the charge holding unit light shielding film 140 and the charge transfer unit light shielding film 150 can be simplified.

The groove portion 152 may be formed toward the light receiving face of the semiconductor substrate 120. As a result, elements other than the photoelectric conversion unit 101 of the pixel 100 can be easily disposed.

Furthermore, the imaging element may further include the groove portion 144 that is a groove disposed on a side facing the groove portion 142 at a boundary of the pixel 100, disposed on a same face of the semiconductor substrate 120 as the face on which the groove portion 142 is formed, and configured to have a length reaching the groove portion 152 from the first side, and the groove portion 154 that is a groove disposed on a side facing the groove portion 152 at a boundary of the pixel 100, disposed on a same face of the semiconductor substrate 120 as the face on which the groove portion 152 is formed, and configured to have a length reaching the groove portion 142 from the second side, in which the charge holding unit adjacent gap 141 may be formed by etching the semiconductor substrate 120 in a vicinity of bottom portions of the groove portion 142 and the groove portion 144 in a direction of the crystal orientation <110>, and the charge transfer unit adjacent gap 151 may be formed by etching the semiconductor substrate 120 in a vicinity of bottom portions of the groove portion 152 and the groove portion 154 in a direction of the crystal orientation <110>. As a result, the formation of the charge holding unit adjacent gap 141 and the charge transfer unit adjacent gap 151 can be speeded up.

Furthermore, the light shielding wall 147 that is disposed in the groove portion 144 and shields incident light may be further included. This makes it possible to shield light obliquely incident from the adjacent pixels 100.

Furthermore, the light shielding wall 157 that is disposed in the groove portion 154 and shields incident light may be further included. This makes it possible to shield light obliquely incident from the adjacent pixels 100.

Furthermore, the imaging element may further include the groove portion 143 disposed on the first side at a boundary of the pixel 100, disposed on a same face of the semiconductor substrate 120 as the face on which the groove portion 142 is formed, and configured to have a depth same as a depth of the groove portion 142, and the groove portion 153 disposed on the second side at a boundary of the pixel 100, disposed on a same face of the semiconductor substrate 120 as the face on which the groove portion 152 is formed, and configured to have a depth same as a depth of the groove portion 152. The formation of the charge holding unit adjacent gap 141 and the charge transfer unit adjacent gap 151 can be speeded up.

Furthermore, the light shielding wall 146 that is disposed in the groove portion 143 and shields incident light may be further included. This makes it possible to shield light obliquely incident from the adjacent pixels 100.

Furthermore, the light shielding wall 156 that is disposed in the groove portion 153 and shields incident light may be further included. This makes it possible to shield light obliquely incident from the adjacent pixels 100.

Further, the groove portion 143 may be configured to have a length so as not to contact the groove portion 142, and the groove portion 153 may be configured to have a length so as not to contact the groove portion 152. This makes it possible to prevent the occurrence of the microloading phenomenon.

Furthermore, the charge holding unit light shielding film 140 may be made of a metal member. Thus, the light shielding ability can be improved.

Furthermore, the charge transfer unit light shielding film 150 may be made of a metal member. Thus, the light shielding ability can be improved.

Furthermore, the imaging device 1000 includes the pixel 100, the charge holding unit light shielding film 140, the charge transfer unit light shielding film 150, the image signal generation unit 110, and the processing circuit (column signal processing unit 30). The pixel 100 includes the photoelectric conversion unit 101 that is disposed on the light receiving face of the semiconductor substrate 120 and performs photoelectric conversion on incident light, the first charge holding unit 107 that is disposed on a side different from a side of the light receiving face of the semiconductor substrate 120 and holds a charge generated by the photoelectric conversion, and the first charge transfer unit 102 that transfers the generated charge to the first charge holding unit 107, and is configured to have a rectangular shape in a light receiving face view. The charge holding unit light shielding film 140 is configured to have a band shape adjacent to three sides including a first side that is one of the sides of the rectangle and parallel to the first side in a light receiving face view, is adjacent to a semiconductor region (region 127) including the first charge transfer unit 102 in a light receiving face view, and is disposed in the pixel 100 between the photoelectric conversion unit and the first charge holding unit 107 to shield incident light. The charge transfer unit light shielding film 150 is configured to have a band shape adjacent to three sides including a second side that is a side facing the first side in a light receiving face view and parallel to the second side, and is configured to have a shape disposed in the pixel 100 between the photoelectric conversion unit and the first charge transfer unit 102 to shield incident light and have an end portion overlapping an end portion of the charge holding unit light shielding film 140 in a light receiving face view. The image signal generation unit 110 generates an image signal based on the held charge. The processing circuit (column signal processing unit 30) processes the generated image signal. Thus, the first charge holding unit 107 can be shielded from light.

Furthermore, the method of manufacturing the imaging element includes forming the pixel 100, forming the charge holding unit light shielding film 140, and forming the charge transfer unit light shielding film 150. Forming the pixel 100 includes forming a pixel that includes a photoelectric conversion unit that is disposed on the light receiving face side of the semiconductor substrate 120 and performs photoelectric conversion on incident light, a first charge holding unit 107 that is disposed on a side different from a side of the light receiving face of the semiconductor substrate 120 and holds a charge generated by the photoelectric conversion, and a first charge transfer unit 102 that transfers the generated charge to the first charge holding unit 107, and is configured to have a rectangular shape in a light receiving face view. Forming the charge holding unit light shielding film 140 includes forming a charge holding unit light shielding film that is configured to have a band shape adjacent to three sides including a first side that is one of the sides of the rectangle and parallel to the first side in a light receiving face view, is adjacent to a semiconductor region including the first charge transfer unit 102 in a light receiving face view, and is disposed in the pixel 100 between the photoelectric conversion unit and the first charge holding unit 107 to shield incident light. Forming the charge transfer unit light shielding film 150 includes forming a charge transfer unit light shielding film that is configured to have a band shape adjacent to three sides including a second side that is a side facing the first side in a light receiving face view and parallel to the second side, and is configured to have a shape disposed in the pixel 100 between the photoelectric conversion unit and the first charge transfer unit 102 to shield incident light and have an end portion overlapping an end portion of the charge holding unit light shielding film 140 in a light receiving face view. Thus, the first charge holding unit 107 can be shielded from light.

Further, the effects described in the present identification are merely examples and are not limited, and other effects may be present.

Note that the present technology may also be configured as below.

(1) An imaging element comprising:
a pixel that includes a photoelectric conversion unit that is disposed on a side of a light receiving face of a semiconductor substrate and performs photoelectric conversion on incident light, a charge holding unit that is disposed on a side different from the light receiving face of the semiconductor substrate and holds a charge generated by the photoelectric conversion, and a charge transfer unit that transfers the generated charge to the charge holding unit, the pixel being configured to have a rectangular shape in a light receiving face view;
a charge holding unit light shielding film configured to have a band shape adjacent to three sides including a first side that is one of sides of the rectangle and parallel to the first side in a light receiving face view, being adjacent to a semiconductor region including the charge transfer unit in a light receiving face view, and being disposed in the pixel between the photoelectric conversion unit and the charge holding unit to shield incident light; and
a charge transfer unit light shielding film configured to have a band shape adjacent to three sides including a second side that is a side opposite to the first side and parallel to the second side in a light receiving face view, and configured to be disposed in the pixel between the photoelectric conversion unit and the charge transfer unit to shield incident light and have a shape which has an end portion overlapping an end portion of the charge holding unit light shielding film in a light receiving face view.
   (2) The imaging element according to the above (1), wherein
the semiconductor substrate has a face of a plane direction (111) orthogonal to a thickness direction, a face opposite the face constituting the light receiving face,
the charge holding unit light shielding film includes a light shielding member disposed in a charge holding unit adjacent gap that is a gap formed by etching the semiconductor substrate in a direction of a crystal orientation <110>, and
the charge transfer unit light shielding film includes a light shielding member disposed in a charge transfer unit adjacent gap that is a gap formed by etching the semiconductor substrate in a direction of the crystal orientation <110>.
   (3) The imaging element according to the above (2), further comprising:
a first charge holding unit adjacent groove that is a groove disposed on one of sides adjacent to the first side at a boundary of the pixel, configured to be parallel to a crystal orientation <112>, and configured to have a length reaching a vicinity of an end portion of the charge holding unit light shielding film from the first side; and
a first charge transfer unit adjacent groove that is a groove disposed on a side facing a side on which the first charge holding unit adjacent groove is disposed at a boundary of the pixel, configured to be parallel to the crystal orientation <112>, and configured to have a length reaching a vicinity of an end portion of the charge transfer unit light shielding film from the second side, wherein
the charge holding unit adjacent gap is formed by etching the semiconductor substrate in a vicinity of a bottom portion of the first charge holding unit adjacent groove in a direction of the crystal orientation <110>, and
the charge transfer unit adjacent gap is formed by etching the semiconductor substrate in a vicinity of a bottom portion of the first charge transfer unit adjacent groove in a direction of the crystal orientation <110>.
   (4) The imaging element according to the above (3), further comprising: a first charge holding unit adjacent light shielding wall that is disposed in the first charge holding unit adjacent groove and shields incident light.
   (5) The imaging element according to the above (3), further comprising: a first charge transfer unit adjacent light shielding wall that is disposed in the first charge transfer unit adjacent groove and shields incident light.
   (6) The imaging element according to the above (3), wherein the first charge holding unit adjacent groove is formed on a same face of the semiconductor substrate as the face on which the first charge transfer unit adjacent groove is formed.
   (7) The imaging element according to the above (6), wherein the first charge transfer unit adjacent groove is formed on the side of the light receiving face of the semiconductor substrate.
   (8) The imaging element according to any one of the above (3) to (7), further comprising:
a second charge holding unit adjacent groove that is a groove disposed on a side facing the first charge holding unit adjacent groove at a boundary of the pixel, disposed on a same face of the semiconductor substrate as the face on which the first charge holding unit adjacent groove is formed, and configured to have a length reaching the first charge transfer unit adjacent groove from the first side; and
a second charge transfer unit adjacent groove that is a groove disposed on a side facing the first charge transfer unit adjacent groove at a boundary of the pixel, disposed on a same face of the semiconductor substrate as the face on which the first charge transfer unit adjacent groove is formed, and configured to have a length reaching the first charge holding unit adjacent groove from the second side, wherein
the charge holding unit adjacent gap is formed by etching the semiconductor substrate in a vicinity of bottom portions of the first charge holding unit adjacent groove and the second charge holding unit adjacent groove in a direction of the crystal orientation <110>, and
the charge transfer unit adjacent gap is formed by etching the semiconductor substrate in a vicinity of bottom portions of the first charge transfer unit adjacent groove and the second charge transfer unit adjacent groove in a direction of the crystal orientation <110>.
   (9) The imaging element according to the above (8), further comprising: a second charge holding unit adjacent light shielding wall that is disposed in the second charge holding unit adjacent groove and shields incident light.
   (10) The imaging element according to the above (8), further comprising: a second charge transfer unit adjacent light shielding wall that is disposed in the second charge transfer unit adjacent groove and shields incident light.
   (11) The imaging element according to the above (8), further comprising:
a third charge holding unit adjacent groove disposed on the first side at a boundary of the pixel, disposed on a same face of the semiconductor substrate as the face on which the first charge holding unit adjacent groove is formed, and configured to have a depth same as a depth of the first charge holding unit adjacent groove; and
a third charge transfer unit adjacent groove disposed on the second side at a boundary of the pixel, disposed on a same face of the semiconductor substrate as the face on which the first charge transfer unit adjacent groove is formed, and configured to have a depth same as a depth of the first charge transfer unit adjacent groove.
   (12) The imaging element according to the above (11), further comprising: a third charge holding unit adjacent light shielding wall that is disposed in the third charge holding unit adjacent groove and shields incident light.
   (13) The imaging element according to the above (11), further comprising: a third charge transfer unit adjacent light shielding wall that is disposed in the third charge transfer unit adjacent groove and shields incident light.
   (14) The imaging element according to the above (11), wherein
the third charge holding unit adjacent groove is configured to have a length so as not to contact the first charge holding unit adjacent groove, and
the third charge transfer unit adjacent groove is configured to have a length so as not to contact the first charge transfer unit adjacent groove.
   (15) The imaging element according to any one of the above (1) to (14), wherein the charge holding unit light shielding film includes a metal member.
   (16) The imaging element according to any one of the above (1) to (15), wherein the charge transfer unit light shielding film includes a metal member.
   (17) An imaging device comprising:
a pixel that includes a photoelectric conversion unit that is disposed on a side of a light receiving face of a semiconductor substrate and performs photoelectric conversion on incident light, a charge holding unit that is disposed on a side different from the light receiving face of the semiconductor substrate and holds a charge generated by the photoelectric conversion, and a charge transfer unit that transfers the generated charge to the charge holding unit, the pixel being configured to have a rectangular shape in a light receiving face view;
a charge holding unit light shielding film configured to have a band shape adjacent to three sides including a first side that is one of sides of the rectangle and parallel to the first side in a light receiving face view, being adjacent to a semiconductor region including the charge transfer unit in a light receiving face view, and being disposed in the pixel between the photoelectric conversion unit and the charge holding unit to shield incident light;
a charge transfer unit light shielding film configured to have a band shape adjacent to three sides including a second side that is a side opposite to the first side and parallel to the second side in a light receiving face view, and configured to be disposed in the pixel between the photoelectric conversion unit and the charge transfer unit to shield incident light and have a shape which has an end portion overlapping an end portion of the charge holding unit light shielding film in a light receiving face view;
an image signal generation unit that generates an image signal based on the held charge; and
a processing circuit that processes the generated image signal.
   (18) A method of manufacturing an imaging element, the method comprising:
a step of forming a pixel that includes a photoelectric conversion unit that is disposed on a side of a light receiving face of a semiconductor substrate and performs photoelectric conversion on incident light, a charge holding unit that is disposed on a side different from the light receiving face of the semiconductor substrate and holds a charge generated by the photoelectric conversion, and a charge transfer unit that transfers the generated charge to the charge holding unit, the pixel being configured to have a rectangular shape in a light receiving face view;
a step of forming a charge holding unit light shielding film configured to have a band shape adjacent to three sides including a first side that is one of sides of the rectangle and parallel to the first side in a light receiving face view, being adjacent to a semiconductor region including the charge transfer unit in a light receiving face view, and being disposed in the pixel between the photoelectric conversion unit and the charge holding unit to shield incident light; and
a step of forming a charge transfer unit light shielding film configured to have a band shape adjacent to three sides including a second side that is a side opposite to the first side and parallel to the second side in a light receiving face view, and configured to be disposed in the pixel between the photoelectric conversion unit and the charge transfer unit to shield incident light and have a shape which has an end portion overlapping an end portion of the charge holding unit light shielding film in a light receiving face view.

### REFERENCE SIGNS LIST

1, 1001 IMAGING ELEMENT
10 PIXEL ARRAY UNIT
30 COLUMN SIGNAL PROCESSING UNIT
100 PIXEL
101 PHOTOELECTRIC CONVERSION UNIT
102 FIRST CHARGE TRANSFER UNIT
103 OVERFLOW GATE
104 SECOND CHARGE TRANSFER UNIT
105 THIRD CHARGE TRANSFER UNIT
106 RESET UNIT
107 FIRST CHARGE HOLDING UNIT
108 SECOND CHARGE HOLDING UNIT
110 IMAGE SIGNAL GENERATION UNIT
120 SEMICONDUCTOR SUBSTRATE
123, 125 GATE ELECTRODE
127 REGION
128, 129 INSULATING FILM
130 WIRING REGION
140, 160 CHARGE HOLDING UNIT LIGHT SHIELDING FILM
141 CHARGE HOLDING UNIT ADJACENT GAP
142 to 144, 148 GROOVE PORTION
145 to 147 LIGHT SHIELDING WALL
150 CHARGE TRANSFER UNIT LIGHT SHIELDING FILM
151 CHARGE TRANSFER UNIT ADJACENT GAP
152 to 154, 158 GROOVE PORTION
155 to 157 LIGHT SHIELDING WALL
180 LIGHT SHIELDING WALL
301 OVERLAPPING PORTION
331 FIRST SIDE
332 SECOND SIDE
1000 IMAGING DEVICE

1. An imaging element comprising:
a pixel that includes a photoelectric conversion unit that is disposed on a side of a light receiving face of a semiconductor substrate and performs photoelectric conversion on incident light, a charge holding unit that is disposed on a side different from the light receiving face of the semiconductor substrate and holds a charge generated by the photoelectric conversion, and a charge transfer unit that transfers the generated charge to the charge holding unit, the pixel being configured to have a rectangular shape in a light receiving face view;
a charge holding unit light shielding film configured to have a band shape adjacent to three sides including a first side that is one of sides of the rectangle and parallel to the first side in a light receiving face view, being adjacent to a semiconductor region including the charge transfer unit in a light receiving face view, and being disposed in the pixel between the photoelectric conversion unit and the charge holding unit to shield incident light; and
a charge transfer unit light shielding film configured to have a band shape adjacent to three sides including a second side that is a side opposite to the first side and parallel to the second side in a light receiving face view, and configured to be disposed in the pixel between the photoelectric conversion unit and the charge transfer unit to shield incident light and have a shape which has an end portion overlapping an end portion of the charge holding unit light shielding film in a light receiving face view.

2. The imaging element according to claim 1, wherein
the semiconductor substrate has a face of a plane direction (111) orthogonal to a thickness direction, a face opposite the face constituting the light receiving face,
the charge holding unit light shielding film includes a light shielding member disposed in a charge holding unit adjacent gap that is a gap formed by etching the semiconductor substrate in a direction of a crystal orientation <110>, and
the charge transfer unit light shielding film includes a light shielding member disposed in a charge transfer unit adjacent gap that is a gap formed by etching the semiconductor substrate in a direction of the crystal orientation <110>.

3. The imaging element according to claim 2, further comprising:
a first charge holding unit adjacent groove that is a groove disposed on one of sides adjacent to the first side at a boundary of the pixel, configured to be parallel to a crystal orientation <112>, and configured to have a length reaching a vicinity of an end portion of the charge holding unit light shielding film from the first side; and
a first charge transfer unit adjacent groove that is a groove disposed on a side facing a side on which the first charge holding unit adjacent groove is disposed at a boundary of the pixel, configured to be parallel to the crystal orientation <112>, and configured to have a length reaching a vicinity of an end portion of the charge transfer unit light shielding film from the second side, wherein
the charge holding unit adjacent gap is formed by etching the semiconductor substrate in a vicinity of a bottom portion of the first charge holding unit adjacent groove in a direction of the crystal orientation <110>, and
the charge transfer unit adjacent gap is formed by etching the semiconductor substrate in a vicinity of a bottom portion of the first charge transfer unit adjacent groove in a direction of the crystal orientation <110>.

4. The imaging element according to claim 3, further comprising: a first charge holding unit adjacent light shielding wall that is disposed in the first charge holding unit adjacent groove and shields incident light.

5. The imaging element according to claim 3, further comprising: a first charge transfer unit adjacent light shielding wall that is disposed in the first charge transfer unit adjacent groove and shields incident light.

6. The imaging element according to claim 3, wherein the first charge holding unit adjacent groove is formed on a same face of the semiconductor substrate as the face on which the first charge transfer unit adjacent groove is formed.

7. The imaging element according to claim 6, wherein the first charge transfer unit adjacent groove is formed on the side of the light receiving face of the semiconductor substrate.

8. The imaging element according to claim 3, further comprising:
a second charge holding unit adjacent groove that is a groove disposed on a side facing the first charge holding unit adjacent groove at a boundary of the pixel, disposed on a same face of the semiconductor substrate as the face on which the first charge holding unit adjacent groove is formed, and configured to have a length reaching the first charge transfer unit adjacent groove from the first side; and
a second charge transfer unit adjacent groove that is a groove disposed on a side facing the first charge transfer unit adjacent groove at a boundary of the pixel, disposed on a same face of the semiconductor substrate as the face on which the first charge transfer unit adjacent groove is formed, and configured to have a length reaching the first charge holding unit adjacent groove from the second side, wherein
the charge holding unit adjacent gap is formed by etching the semiconductor substrate in a vicinity of bottom portions of the first charge holding unit adjacent groove and the second charge holding unit adjacent groove in a direction of the crystal orientation <110>, and
the charge transfer unit adjacent gap is formed by etching the semiconductor substrate in a vicinity of bottom portions of the first charge transfer unit adjacent groove and the second charge transfer unit adjacent groove in a direction of the crystal orientation <110>.

9. The imaging element according to claim 8, further comprising: a second charge holding unit adjacent light shielding wall that is disposed in the second charge holding unit adjacent groove and shields incident light.

10. The imaging element according to claim 8, further comprising: a second charge transfer unit adjacent light shielding wall that is disposed in the second charge transfer unit adjacent groove and shields incident light.

11. The imaging element according to claim 8, further comprising:
a third charge holding unit adjacent groove disposed on the first side at a boundary of the pixel, disposed on a same face of the semiconductor substrate as the face on which the first charge holding unit adjacent groove is formed, and configured to have a depth same as a depth of the first charge holding unit adjacent groove; and
a third charge transfer unit adjacent groove disposed on the second side at a boundary of the pixel, disposed on a same face of the semiconductor substrate as the face on which the first charge transfer unit adjacent groove is formed, and configured to have a depth same as a depth of the first charge transfer unit adjacent groove.

12. The imaging element according to claim 11, further comprising: a third charge holding unit adjacent light shielding wall that is disposed in the third charge holding unit adjacent groove and shields incident light.

13. The imaging element according to claim 11, further comprising: a third charge transfer unit adjacent light shielding wall that is disposed in the third charge transfer unit adjacent groove and shields incident light.

14. The imaging element according to claim 11, wherein
the third charge holding unit adjacent groove is configured to have a length so as not to contact the first charge holding unit adjacent groove, and
the third charge transfer unit adjacent groove is configured to have a length so as not to contact the first charge transfer unit adjacent groove.

15. The imaging element according to claim 1, wherein the charge holding unit light shielding film includes a metal member.

16. The imaging element according to claim 1, wherein the charge transfer unit light shielding film includes a metal member.

17. An imaging device comprising:
a pixel that includes a photoelectric conversion unit that is disposed on a side of light receiving face of a semiconductor substrate and performs photoelectric conversion on incident light, a charge holding unit that is disposed on a side different from the light receiving face of the semiconductor substrate and holds a charge generated by the photoelectric conversion, and a charge transfer unit that transfers the generated charge to the charge holding unit, the pixel being configured to have a rectangular shape in a light receiving face view;
a charge holding unit light shielding film configured to have a band shape adjacent to three sides including a first side that is one of sides of the rectangle and parallel to the first side in a light receiving face view, being adjacent to a semiconductor region including the charge transfer unit in a light receiving face view, and being disposed in the pixel between the photoelectric conversion unit and the charge holding unit to shield incident light;
a charge transfer unit light shielding film configured to have a band shape adjacent to three sides including a second side that is a side opposite to the first side and parallel to the second side in a light receiving face view, and configured to be disposed in the pixel between the photoelectric conversion unit and the charge transfer unit to shield incident light and have a shape which has an end portion overlapping an end portion of the charge holding unit light shielding film in a light receiving face view;
an image signal generation unit that generates an image signal based on the held charge; and
a processing circuit that processes the generated image signal.

18. A method of manufacturing an imaging element, the method comprising:
a step of forming a pixel that includes a photoelectric conversion unit that is disposed on a side of a light receiving face of a semiconductor substrate and performs photoelectric conversion on incident light, a charge holding unit that is disposed on a side different from the light receiving face of the semiconductor substrate and holds a charge generated by the photoelectric conversion, and a charge transfer unit that transfers the generated charge to the charge holding unit, the pixel being configured to have a rectangular shape in a light receiving face view;
a step of forming a charge holding unit light shielding film configured to have a band shape adjacent to three sides including a first side that is one of sides of the rectangle and parallel to the first side in a light receiving face view, being adjacent to a semiconductor region including the charge transfer unit in a light receiving face view, and being disposed in the pixel between the photoelectric conversion unit and the charge holding unit to shield incident light; and
a step of forming a charge transfer unit light shielding film configured to have a band shape adjacent to three sides including a second side that is a side opposite to the first side and parallel to the second side in a light receiving face view, and configured to be disposed in the pixel between the photoelectric conversion unit and the charge transfer unit to shield incident light and have a shape which has an end portion overlapping an end portion of the charge holding unit light shielding film in a light receiving face view.
